(19) United States
(12) Patent Application Publication
(10) Pub. No.: US 2026/0150385 A1
(43) Pub. Date: May 28, 2026

(54) POWER DELIVERY NETWORK (PDN) STRUCTURE IN AN INTEGRATED CIRCUIT (IC) PACKAGE ASSEMBLY

(71) Applicant: Taiwan Semiconductor Manufacturing Company, Ltd., Hsinchu (TW)

(72) Inventors: Tai-Chun Huang, New Taipei City (TW); Lan-Chou Cho, Hsinchu City (TW); Stefan Rusu, Sunnyvale, CA (US); Jen-Yuan Chang, Hsinchu City (TW)

(21) Appl. No.: 18/960,945

(22) Filed: Nov. 26, 2024

(51) Int. Cl. H10D 84/01; H01L 25/18; H10D 30/00; H10D 30/01; H10D 30/40; H10D 30/62; H10D 30/67; H10D 84/85

(52) U.S. Cl. CPC H10D 84/0186; H10D 30/014; H10D 30/019; H10D 30/024; H10D 30/40; H10D 30/501; H10D 30/6211; H10D 30/6735; H10D 84/0193; H10D 84/853; H10W 90/00

(57) ABSTRACT

An integrated circuit (IC) package assembly includes a photonic integrated circuit (PIC) device and an electronic integrated circuit (EIC) device. The PIC device includes a plurality of photonic components. The photonic components are configured to receive light from a first side of the IC package assembly. The EIC device is bonded to the PIC device from a second side of the IC package assembly. The second side is opposite the first side. The EIC device includes a layer that contains electrical circuitry configured to interact with the photonic components of the PIC device. The EIC device also includes a power delivery network (PDN) structure. The layer is disposed between the PIC and the PDN structure of the EIC.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

As the scaling down process continues, it has brought about certain challenges. For example, it may be beneficial to integrate different types of IC dies (e.g., a photonic IC and an electrical IC) into a same IC package assembly. However, often times these integration schemes lack fabrication process flow efficiency and/or may have sub-optimal performance, such as excessive power consumption or loss of optical energy.

Therefore, although conventional IC package integration schemes have been generally adequate, they have not been satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a perspective view of an IC device according to various aspects of the present disclosure.

FIG. 1B is a planar top view of an IC device according to various aspects of the present disclosure.

FIG. 1C is a cross-sectional side view of an IC device according to various aspects of the present disclosure.

FIGS. 2-23 are cross-sectional side views of various embodiments of an IC package assembly at various stages of fabrication according to various aspects of the present disclosure.

FIG. 24 is a cross-sectional side view of a power delivery network (PDN) structure according to various aspects of the present disclosure.

FIGS. 25 and 27 are cross-sectional side views of an IC device according to embodiments of the present disclosure.

FIGS. 26 and 28 are three-dimensional perspective views of an IC device according to embodiments of the present disclosure.

FIG. 29 is a block diagram of a manufacturing system according to various aspects of the present disclosure.

FIGS. 30-31 are flowcharts illustrating methods of fabricating an IC package assembly according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc., as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to semiconductor devices, and more particularly to integrating an electronic integrated circuit (EIC) and a photonic integrated circuit (PIC) together as an IC package assembly. In more detail, photonic devices may use light (as opposed to electrical signals) to transmit data. For example, computational results obtained by a graphical processing unit (GPU) or a central processing unit (CPU) may be transmitted via photonic devices through light. Such an optical data transmission scheme is faster and/or more efficient than data transmission via purely electrical paths. In some applications, photonic devices themselves may also be used to implement the GPUs or CPUs (or portions thereof).

However, existing methods of integrating photonic devices and electronic devices may still face certain challenges. For example, existing methods of integrating photonic devices and electronic devices together as an IC package assembly may implement a power delivery network (PDN) structure on the same side as an interconnection structure that is used to route the electrical signals. Unfortunately, such an approach may cause crowding within the PDN structure and the rest of the interconnection structure, which may lead to manufacturing difficulties and/or increased electrical resistance. In turn, power consumption is increased, and/or optical energy may be lost.

To address the various issues discussed above, the present disclosure provides a novel process flow for integrating the photonic device and the electronic device together, where the PDN structure and the interconnection structure are implemented on opposite sides. Such an approach reduces manufacturing complexity and allows for greater spacing among conductive components in the PDN structure and/or the interconnection structure. As a result, electrical resistance may be reduced, which may in turn lower power consumption and/or increase speed of operation. Furthermore, the loss of optical energy may be minimized, which enhances optical transmission efficiency.

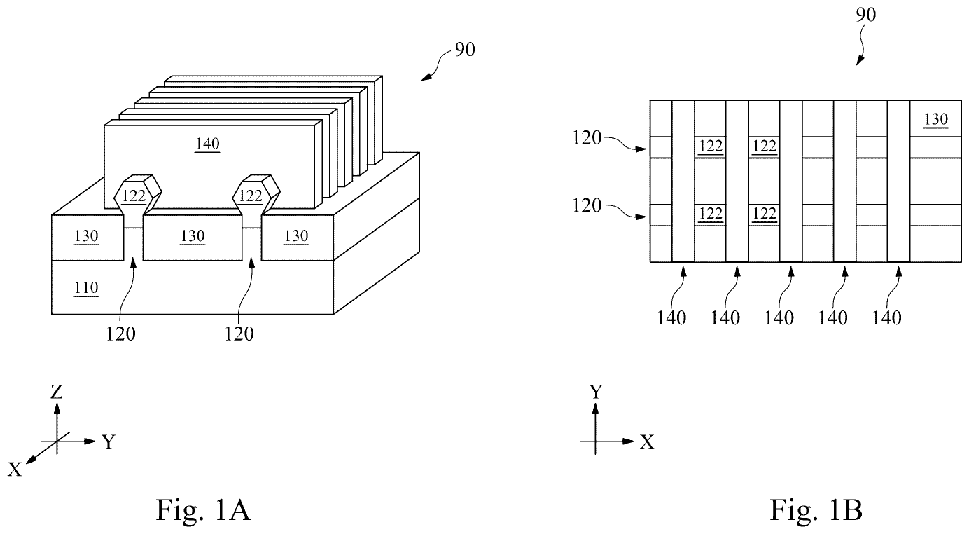

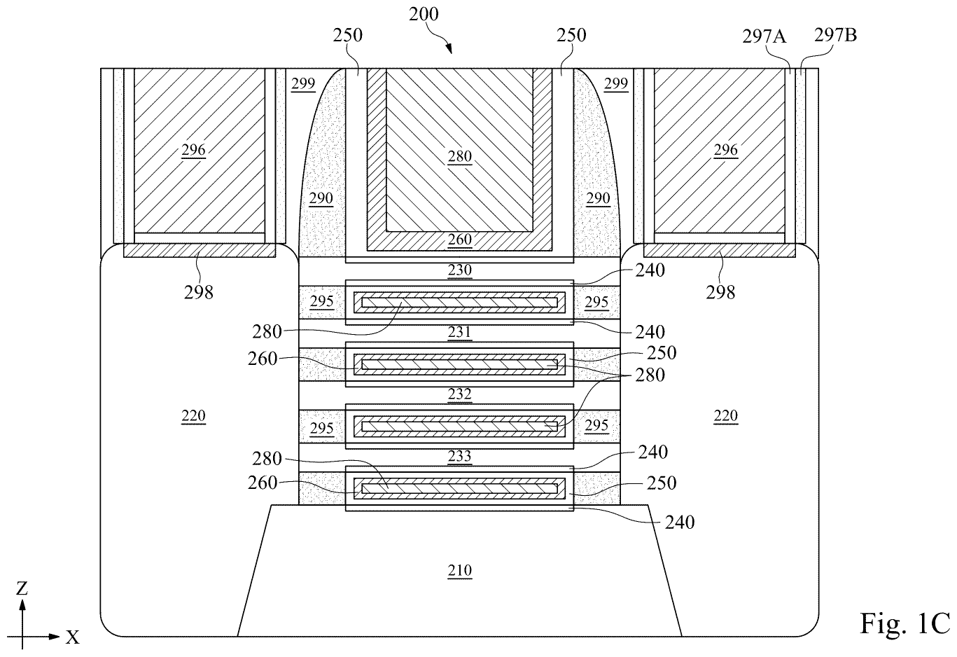

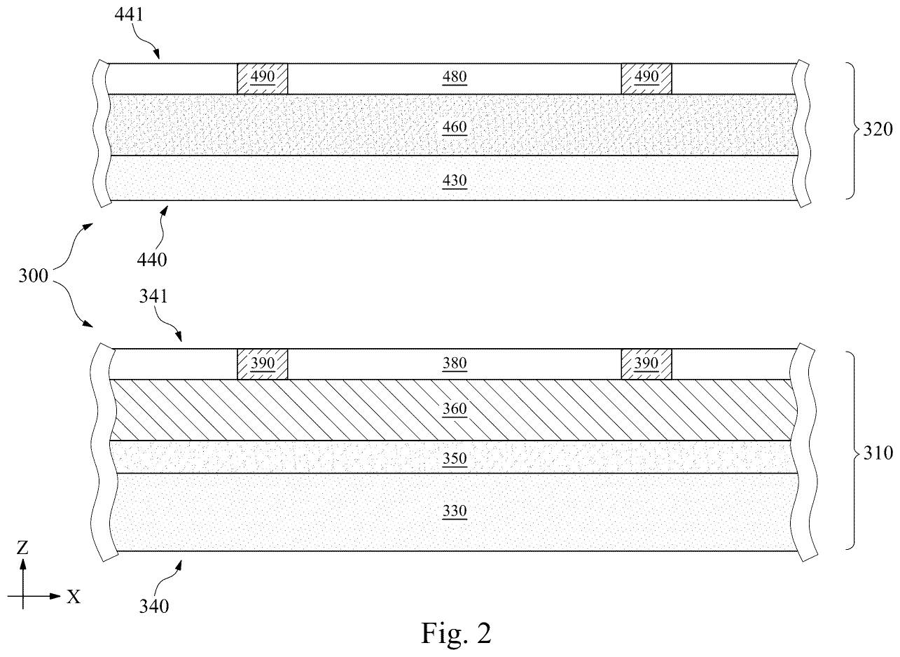

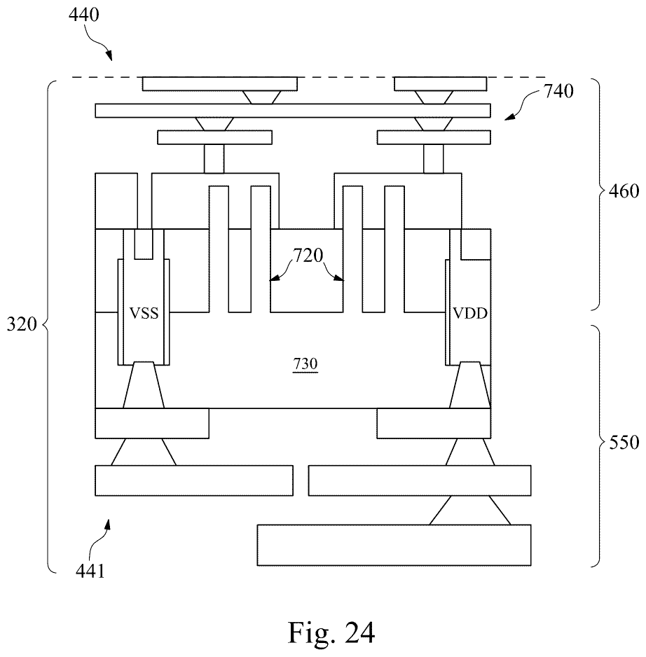

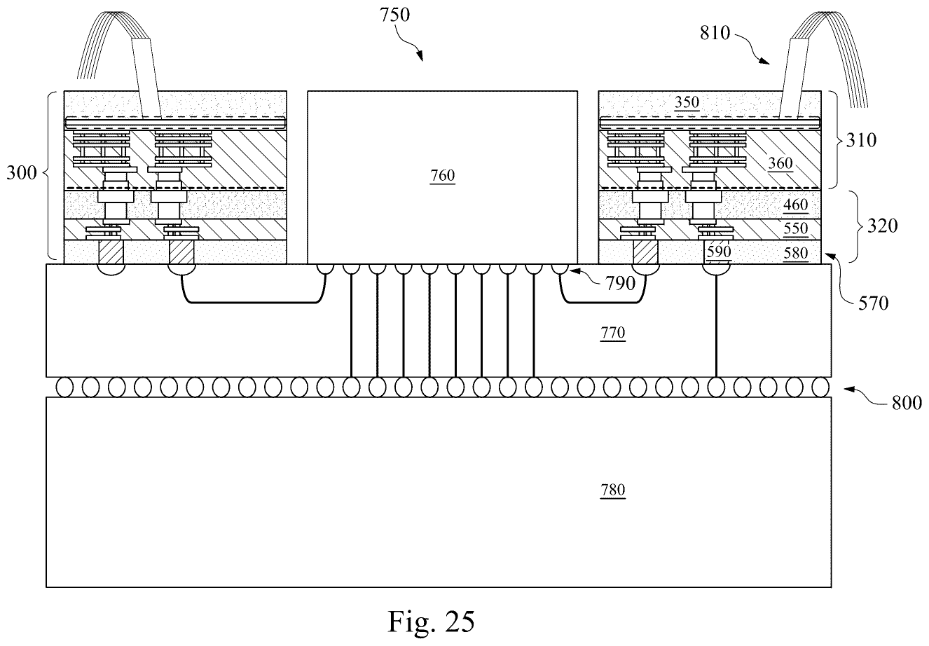

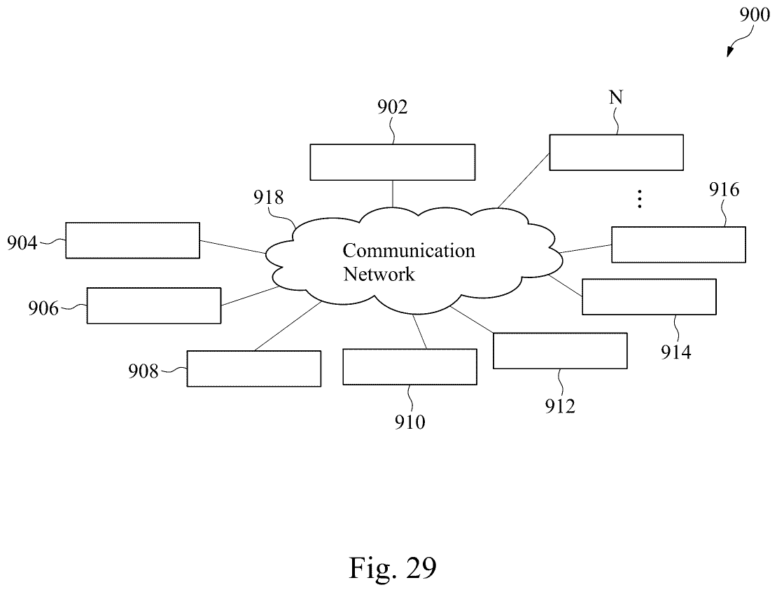

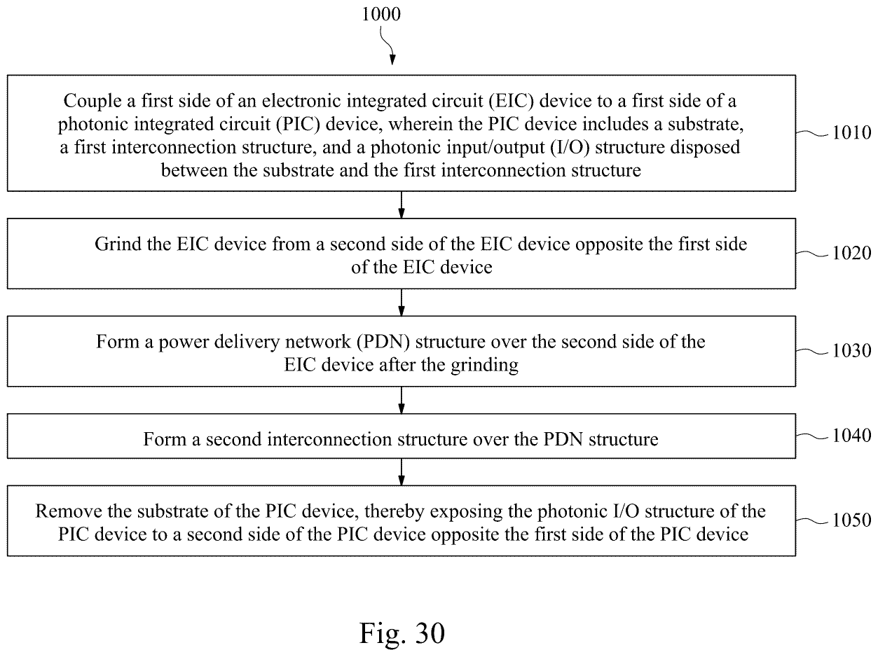

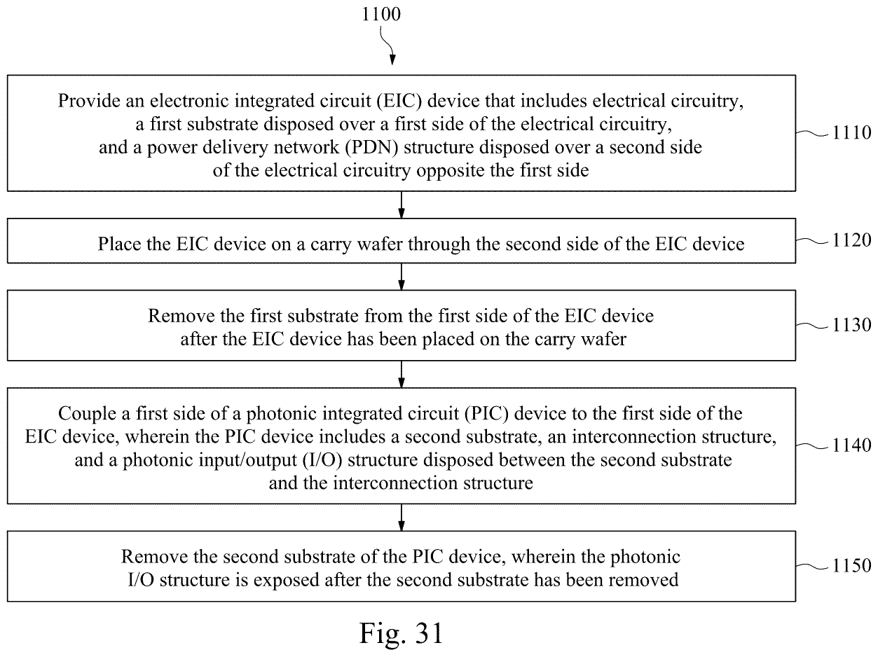

Various aspects of the present disclosure will now be discussed below with reference to FIGS. 1-31. Specifically, FIGS. 1A-1C describe example types of transistors that can be implemented on an IC package assembly that includes a photonic device and an electronic device, FIGS. 2-23 describe an example fabrication process flow used to fabricate an IC package assembly according to an embodiment of the present disclosure, FIG. 24 describes a PDN structure, FIGS. 25-28 describe an IC device on which an IC package assembly is implemented according to embodiments of the present disclosure. FIG. 29 describes an example fabrication system, and FIGS. 30-31 each describes a flowchart corresponding to a method of fabricating an IC package assembly according to an embodiment of the present disclosure.

Referring now to FIGS. 1A-1B, a three-dimensional perspective view and a top view are illustrated, respectively, of a portion of an Integrated Circuit (IC) device 90. The IC device 90 may be an intermediate device fabricated during processing of an IC, or a portion thereof, that may comprise electronic memory circuits and/or other logic circuits, passive components such as resistors, capacitors, and inductors, and active components such as p-type FETs (PFETs), n-type FETs (NFETs), FinFETs, metal-oxide semiconductor field effect transistors (MOSFET), complementary metal-oxide semiconductor (CMOS) transistors, bipolar transistors, high voltage transistors, high frequency transistors, and/or other memory cells. The present disclosure is not limited to any particular number of devices or device regions, or to any particular device configurations, unless otherwise claimed. For example, although the IC device 90 as illustrated is a three-dimensional FinFET device, the concepts of the present disclosure may also apply to planar FET devices or GAA devices.

As shown in FIG. 1A, the IC device 90 includes a substrate 110. The substrate 110 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 110 may be a single-layer material having a uniform composition. Alternatively, the substrate 110 may include multiple material layers having similar or different compositions suitable for IC device manufacturing. In one example, the substrate 110 may be a silicon-on-insulator (SOI) substrate having a semiconductor silicon layer formed on a silicon oxide layer. In another example, the substrate 110 may include a conductive layer, a semiconductor layer, a dielectric layer, other layers, or combinations thereof. Various doped regions, such as source/drain regions, may be formed in or on the substrate 110. The doped regions may be doped with n-type dopants, such as phosphorus or arsenic, and/or p-type dopants, such as boron, depending on design requirements. The doped regions may be formed directly on the substrate 110, in a p-well structure, in an n-well structure, in a dual-well structure, or using a raised structure. Doped regions may be formed by implantation of dopant atoms, in-situ doped epitaxial growth, and/or other suitable techniques.

Three-dimensional active regions 120 are formed on the substrate 110. The active regions 120 are elongated fin-like structures that protrude upwardly out of the substrate 110. As such, the active regions 120 may be interchangeably referred to as fins 120 or fin structures 120 hereinafter. The fin structures 120 may be fabricated using suitable processes including photolithography and etch processes. The photolithography process may include forming a photoresist layer overlying the substrate 110, exposing the photoresist to a pattern, performing post-exposure bake processes, and developing the photoresist to form a masking element (not shown) including the resist. The masking element is then used for etching recesses into the substrate 110, leaving the fin structures 120 on the substrate 110. The etching process may include dry etching, wet etching, reactive ion etching (RIE), and/or other suitable processes. In some embodiments, the fin structure 120 may be formed by double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example, a layer may be formed over a substrate and patterned using a photolithography process. Spacers are formed alongside the patterned layer using a self-aligned process. The layer is then removed, and the remaining spacers, or mandrels, may then be used to pattern the fin structures 120.

The IC device 90 also includes source/drain features 122 formed over the fins 120. The source/drain features 122 may include epi-layers that are epitaxially grown on the fin structures 120. The IC device 90 further includes isolation structures 130 formed over the substrate 110. The isolation structures 130 electrically separate various components of the IC device 90. The isolation structures 130 may include silicon oxide, silicon nitride, silicon oxynitride, fluoride-doped silicate glass (FSG), a low-k dielectric material, and/or other suitable materials. In some embodiments, the isolation structures 130 may include shallow trench isolation (STI) features. In one embodiment, the isolation structures 130 are formed by etching trenches in the substrate 110 during the formation of the fin structures 120. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 130. Alternatively, the isolation structures 130 may include a multi-layer structure, for example, having one or more thermal oxide liner layers.

The IC device 90 also includes gate structures 140 formed over and engaging the fins 120 on three sides in a channel region of each fin 120. The gate structures 140 may be dummy gate structures (e.g., containing an oxide gate dielectric and a polysilicon gate electrode), or they may be HKMG structures that contain a high-k gate dielectric and a metal gate electrode, where the HKMG structures are formed by replacing the dummy gate structures. Though not depicted herein, the gate structure 140 may include additional material layers, such as an interfacial layer over the fins 120, a capping layer, other suitable layers, or combinations thereof.

Referring to FIG. 1B, multiple fins 120 are oriented lengthwise along the X-direction, and multiple gate structure 140 are oriented lengthwise along the Y-direction, i.e., generally perpendicular to the fins 120. In many embodiments, the IC device 90 includes additional features such as gate spacers disposed along sidewalls of the gate structures 140, hard mask layer(s) disposed over the gate structures 140, and numerous other features.

FIG. 1C illustrates a diagrammatic cross-sectional side view of a portion of an IC device 200 fabricated according to embodiments of the present disclosure, where the IC device 200 is a gate-all-around (GAA) device and may be referred to as a GAA device 200 hereinafter. It is understood that the GAA device 200 may be an NFET in some embodiments, or it may be a PFET in other embodiments.

Referring to FIG. 1C, the cross-sectional view of the GAA device 200 is taken along an X-Z plane, where the X-direction (same X-direction as in FIG. 1A) is the horizontal direction, and the Z-direction (same Z-direction as in FIG. 1A) is the vertical direction. The GAA device 200 includes a fin structure 210, which may be similar to the fin structure 120 discussed above. In some embodiments, the fin structure 210 includes silicon. The GAA device 200 includes source/drain features 220, which may be similar to the source/drain features 122 discussed above. In embodiments where the GAA device 200 is an NFET, the source/drain features 220 include silicon phosphorous (SiP). In embodiments where the GAA device 200 is a PFET, the source/drain features 220 include silicon germanium (SiGe).

The GAA device 200 includes a plurality of channels, for example channels 230-233 as shown in FIG. 1C. The channels 230-233 each include a semiconductive material, for example silicon or a silicon compound. The channels 230-233 are nanostructures (e.g., having sizes that are in a range of a few nanometers) and may also each have an elongated shape and extend in the X-direction. In some embodiments, the channels 230-233 may each have a nano-wire shape, a nano-sheet shape, a nano-tube shape, etc. The cross-sectional profile of the nano-wire, nano-sheet, or nano-tube may be round/circular, square, rectangular, hexagonal, elliptical, or combinations thereof.

In some embodiments, the lengths (e.g., measured in the X-direction) of the channels 230-233 may be different from each other. For example, a length of the channel 230 may be less than a length of the channel 231, which may be less than a length of the channel 232, which may be less than a length of the channel 233. In some embodiments, each of the channels 230-233 may not have uniform thicknesses.

In some embodiments, a spacing (e.g., measured in the Z-direction) between the channels 230-233 (each channel from adjacent channels) is in a range between about 2 nanometers (nm) and about 12 nm. In some embodiments, a thickness (e.g., measured in the Z-direction) of each of the channels 230-233 is in a range between about 5 nm and about 2 nm. In some embodiments, a width (e.g., measured in the Y-direction of FIG. 1A) of each of the channels 230-233 is in a range between about 15 nm and about 150 nm. A plurality of interfacial layers (ILs) 240 may also be formed on the upper and lower surfaces of the channels 230-233.

The GAA device 200 also includes gate structures that are disposed over and in between the channels 230-233. The gate structures may include gate dielectric layers 250. In some embodiments, the gate dielectric layers 250 include a high-k gate dielectric. The gate structures further include one or more work function metal layers 260. In embodiments where the GAA device 200 is an NFET, the one or more work function metal layers 260 include N-type work function metal layers, such as TiAlC. In embodiments where the GAA device 200 is a PFET, the one or more work function metal layers 260 include P-type work function metal layers, such as TiN.

The gate structures also include fill metals 280. In the portion of the gate structure formed over the channels 230-233, the fill metal 280 are formed over the one or more work function metal layers 260. The one or more work function metal layers 260 have a U-shape and wrap around the fill metal 280, and the gate dielectric layer 250 also has a U-shape and wrap around the one or more work function metal layers 260. In portions of the gate structures formed between the channels 230-233, the fill metal 280 is circumferentially surrounded (in the cross-sectional view) by the one or more work function metal layers 260, which is then circumferentially surrounded by the gate dielectric layer 250. It is understood that the gate structures may also include a glue layer that is formed between the one or more work function metal layers 260 and the fill metal 280 to increase adhesion. However, for reasons of simplicity, such a glue layer is not specifically illustrated herein.

The GAA device 200 also includes gate spacers 290 and inner spacers 295 that are disposed on sidewalls of the gate dielectric layer 250. The inner spacers 295 are also disposed between the channels 230-233. The gate spacers and the inner spacers 295 may include a dielectric material, for example a low-k material such as SiOCN, SiON, SiN, or SiOC.

The GAA device 200 further includes source/drain contacts 296 that are formed over the source/drain features 220. The source/drain contacts 296 may include a conductive material such as cobalt, copper, aluminum, tungsten, or combinations thereof. The source/drain contacts 296 are surrounded by barrier layers, for example barrier layers 297A and 297B, which help prevent or reduce diffusion of materials from and into the source/drain contacts 296. In some embodiments, the barrier layer 297A includes TiN, and the barrier layer 297B includes SiN. A silicide layer 298 may also be formed between the source/drain features 220 and the source/drain contacts 296, so as to reduce the source/drain contact resistance. The silicide layer 298 may contain a metal silicide material, such as cobalt silicide in some embodiments.

The GAA device 200 further includes an interlayer dielectric (ILD) 299. The ILD 299 provides electrical isolation between the various components of the GAA device 200, for example between the gate structures and the source/drain contacts 296.

The FinFET devices and GAA devices discussed above may be implemented in electronic devices and/or photonic devices that are integrated into an IC package assembly. In that regard, FIGS. 2-23 illustrate diagrammatic fragmentary cross-sectional side views of a portion of an integrated circuit (IC) package assembly 300 at various stages of fabrication according to embodiments of the present disclosure. Each of the cross-sectional side views is taken along an X-direction (as the horizontal direction) and a Z-direction (as the vertical direction).

Referring now to FIG. 2, the IC package assembly 300 includes a photonic IC (PIC) device 310 and an electronic IC (EIC) device 320. The photonic device 310 may include a plurality of photonic components that form photonic circuits for detecting, processing, and/or transmitting light. In comparison, the EIC device 320 may include a plurality of transistors (e.g., the FinFET devices or the GAA devices discussed above) that form electrical circuits that have different applications. For example, the electrical circuits of the EIC device 320 may form a microcontroller to control the operation of the PIC device 310.

The PIC device 310 at this stage of fabrication includes a wafer. For example, the PIC device 310 includes a substrate 330, such as a silicon substrate that is a part of the wafer. The substrate 330 is disposed on a side 340 (in the vertical Z-direction) of the PIC device 310. The PIC device 310 also includes a photonic input/output (I/O) structure 350, which may include photonic components that are configured to input and/or output light. In some embodiments, the photonic I/O structure 350 includes a plurality of microlenses configured to focus light. The photonic I/O structure 350 is located on a side 341 of the substrate 330, which is an opposite side than the side 340 in the vertical Z-direction.

The PIC device 310 further includes an interconnection structure 360, which is disposed on the side 341 of the photonic I/O structure 350. In other words, the photonic I/O structure 350 is disposed between the substrate 330 and the interconnection structure 360. In various embodiments, the interconnection structure 360 may include conductive interconnect features (e.g., metal lines) that may reside in a plurality of interconnect layers (e.g., Metal-0, Metal-1, Metal-2, etc.), as well as conductive vias or conductive contacts for electrically interconnecting the conductive interconnect features together.

A bonding film 380 is formed on the side 341 of the interconnection structure 360. In some embodiments, the bonding film 380 may also be considered to be a part of the PIC device 310. The bonding film 380 may include a dielectric material, such as silicon oxide in some embodiments, or silicon oxynitride in some other embodiments. A plurality of conductive vias, such as conductive vias 390, may be disposed within and extend vertically through the bonding film 380. It is understood that although two of such conductive vias 390 are illustrated in FIG. 2, this is merely for the reason of simplicity, and that the number of conductive vias in the bonding film 380 may greatly exceed two. It is also understood that the conductive vias 390 may be used to align the PIC device 310 with the EIC device 320 in a bonding process that bonds the PIC device 310 and the EIC device 320 together, as discussed in greater detail below.

Still referring to FIG. 2, the EIC device 320 at this stage of fabrication also includes a wafer. For example, the EIC device 320 includes a substrate 430, such as a silicon substrate that is a part of the wafer. The substrate 430 is disposed on a side 440 (in the vertical Z-direction) of the EIC device 320.

The EIC device 320 further includes a layer 460 that is located on a side 441 of the substrate 430, which is an opposite side than the side 440 in the vertical Z-direction. The layer 460 contains electrical circuitry, such as electrical circuitry built by the FinFET devices and/or the GAA devices discussed above with reference to FIGS. 1A-1C. In some embodiments, the electrical circuitry may be configured to control certain aspects of the operation of the PIC device 310, and/or to carry out certain computational tasks. In some embodiments, the electrical circuitry in the layer 460 may include a microcontroller that is configured to control the operation of the PIC device 310. In some embodiments, the EIC device 320 and the PIC device 310 may work in conjunction to transmit signals (e.g., signals that correspond to GPU/CPU computational results) sent by one or more other ICs, which are not specifically illustrated in FIG. 2 for reasons of simplicity. In some embodiments, the layer 460 may also include electrical interconnection structures, such as metal lines, conductive vias, and/or conductive contacts, which are configured to provide electrical connectivity to at least the electrical circuitry of the layer 460.

A bonding film 480 is formed on the side 441 of the layer 460. In some embodiments, the bonding film 480 may also be considered to be a part of the EIC device 320. The bonding film 480 may include a dielectric material, such as silicon oxide in some embodiments, or silicon oxynitride in some other embodiments. A plurality of conductive vias, such as conductive vias 490, may be disposed within and extend vertically through the bonding film 480. Again, it is understood that the actual number of conductive vias in the bonding film 480 may greatly exceed two, and the conductive vias 490 may be used to align the EIC device 320 with the PIC device 310 in a bonding process that bonds the PIC device 310 and the EIC device 320 together, as discussed in greater detail below.

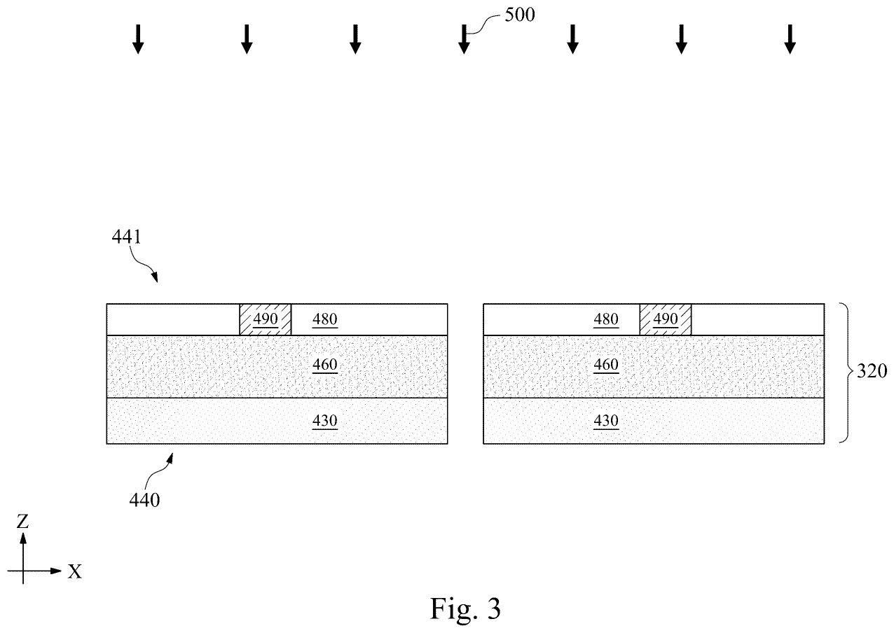

Referring now to FIG. 3, fabrication processes 500 are performed to the EIC device 320. The fabrication processes 500 may include a dicing process. For example, a mechanical saw or a laser saw may be used to dice the EIC device 320 in the vertical Z-direction. The dicing process may be performed until the EIC device 320 is singulated into a desired number of smaller pieces. The EIC device 320 may refer to an individual one of these singulated pieces hereinafter. The fabrication processes 500 may also include a die thinning process, which may be performed from the side 440 of the EIC device 320. In some embodiments, the die thinning process may include a mechanical grinding process and a chemical thinning process. For example, a substantial amount of substrate material may be first removed from the substrate 430 during the mechanical grinding process. Afterwards, the chemical thinning process may apply an etching chemical to the side 440 of the substrate 430 to further thin the substrate 430. As a result of the die thinning process, a thickness of the substrate 430 in the vertical Z-direction is substantially reduced. For example, the substrate 430 may have a thickness on the order of a few microns at the completion of the die thinning process. In some embodiments, the dicing process may be performed before the die thinning process. In other embodiments, the die thinning process may be performed before the dicing process.

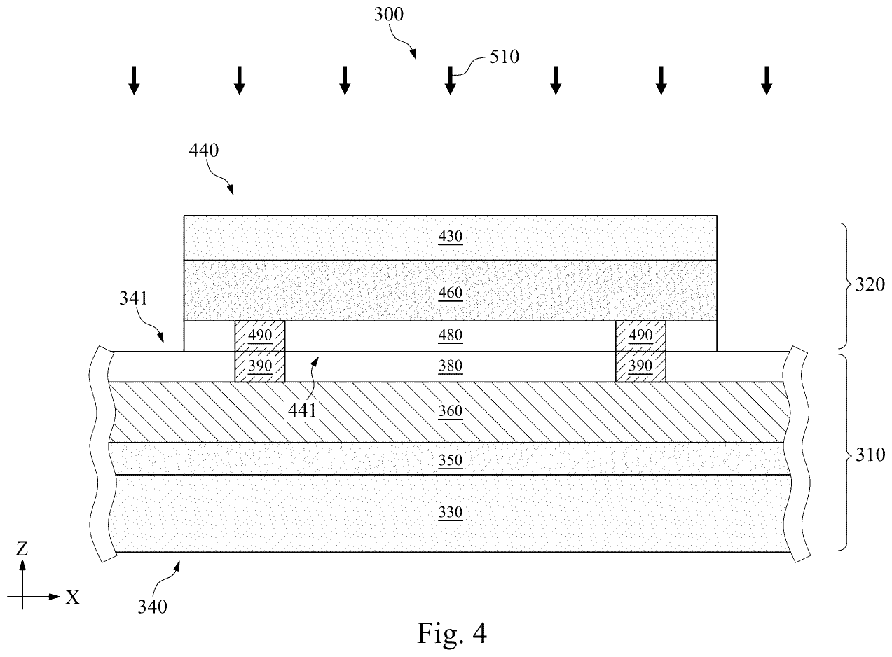

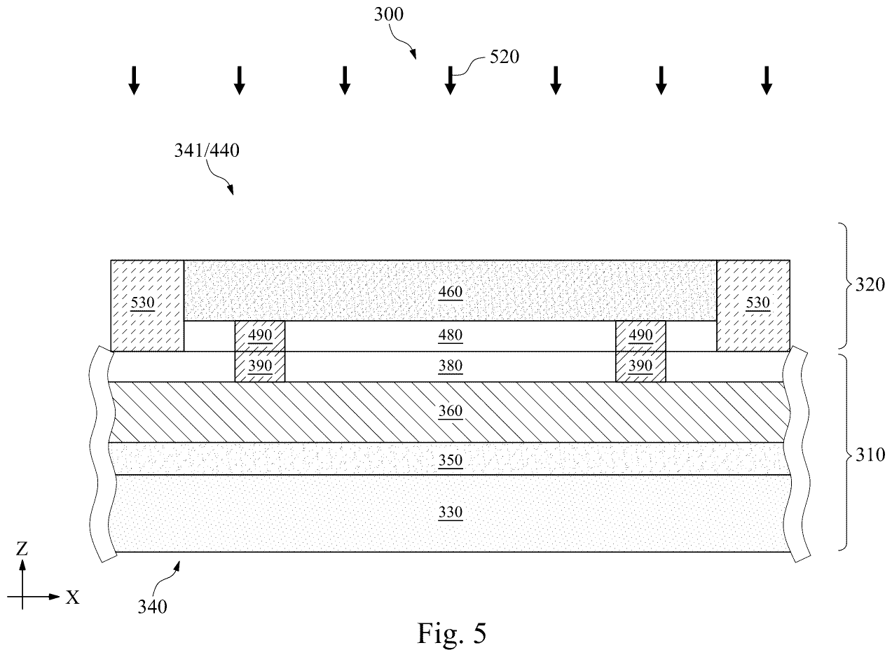

Referring now to FIG. 4, a coupling process 510 is performed to couple the EIC device 320—which is now a singulated die—to the PIC device 310. In some embodiments, the coupling process 510 includes a hybrid bonding process or a pick-and-place process. As a part of the coupling process 510, the EIC device 320 is flipped vertically upside down, such that the side 441 is now facing downwards towards the PIC device 310. The bonding film 480 of the EIC device 320 is now bonded to the bonding film 380 of the PIC device 310. As discussed above, each of the conductive vias 490 is vertically aligned with a respective one of the conductive vias 390. The alignment of the conductive vias 390 and 490 helps ensure that electrical connectivity may be properly established between the EIC device 320 and the PIC device 310. In other words, the EIC device 320 may be able to send and/or receive electrical signals to and/or from the PIC device 310 through the conductive vias 390/490. It is understood that, for reasons of simplicity, FIG. 5 illustrates merely one EIC device 320 (e.g., a singulated die) on the wafer-level structure that is the PIC device 310, but a plurality of other EIC devices 320 may be coupled to the same wafer-level structure of the PIC device 310 (e.g., laterally adjacent to the EIC device 320 illustrated in FIG. 5, but not specifically shown herein).

Referring now to FIG. 5, fabrication processes 520 are performed to the IC package assembly 300. For example, the fabrication processes 520 may include a grinding process that is performed to the side 440 (which is now the same side as the side 341) of the EIC device 320 to remove the substrate 430 and to expose the layer 460 to the side 440. In some embodiments, the grinding process may include a chemical mechanical polishing (CMP) process or another suitable type of planarization process. In addition to removing the substrate 430 from the rest of the EIC device 320, the grinding process also ensures that the surface of the layer 460 exposed to the side 341/440 has a sufficient flatness and/or smoothness for subsequent fabrication processing.

The fabrication processes 520 may also include one or more deposition processes to form a gap filling material 530 to fill the gaps formed as a result of the EIC device 320 having a narrower dimension than the PIC device 310. In some embodiments, the deposition processes may include a chemical vapor deposition (CVD), a physical vapor deposition (PVD), an atomic layer deposition (ALD), or combinations thereof. The gap filling material 530 may be deposited onto the surfaces of the interconnection structure 360 exposed to the side 341/440 (i.e., the portions that are not covered by the EIC device 320). The gap filling material 530 also laterally surrounds the side surfaces of the EIC device 320, for example, the side surfaces of the layer 460 and the bonding film 480. In some embodiments, the gap filling material 530 may include a suitable dielectric material, such as silicon carbide, silicon nitride, silicon oxide, silicon oxynitride, or combinations thereof.

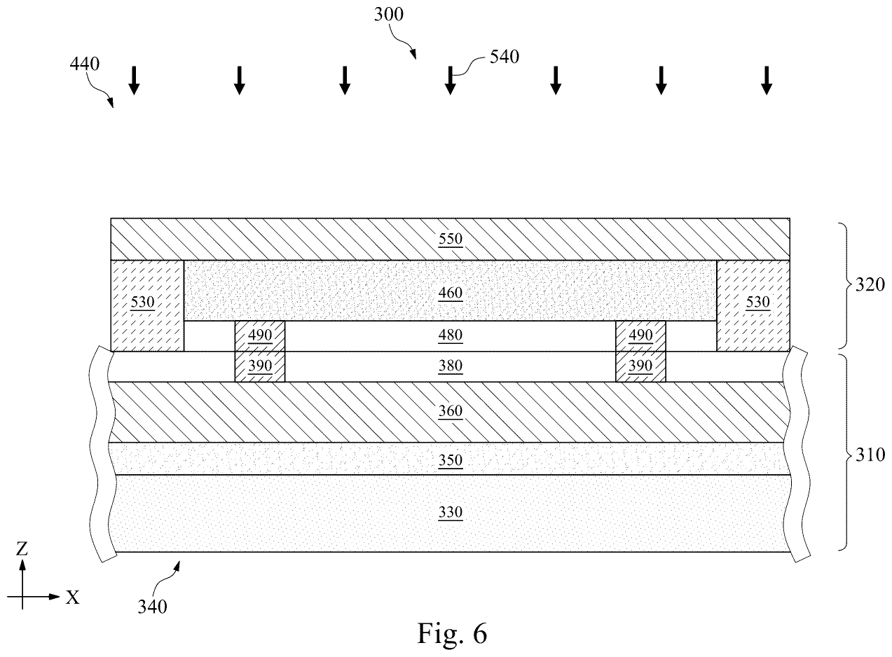

Referring now to FIG. 6, fabrication processes 540 are performed to the IC package assembly 300 to form a power delivery network (PDN) structure 550 over the side 440 of the EIC device 320. In other words, the PDN structure 550 may be formed on the surfaces of the layer 460 and the gap filling material 530. In some embodiments, the PDN structure 550 is a structure that delivers power and ground voltages from conductive pad locations to the various components (e.g., circuitry made of transistors such as the FinFET or GAA devices discussed above) of the IC package assembly 300. In some embodiments, the PDN structure 550 includes a plurality of layers, where each layer includes one or more power rails and/or ground rails. The power rails or ground rails may be in the form of metal lines. The various layers of the PDN structure 550 may be electrically interconnected together by conductive vias. Electrical connectivity to the PDN structure 550 (and to the rest of the IC package assembly 300) may be gained by conductive bumps that will be formed in a later fabrication step. An example embodiment of the PDN structure 550 will be discussed below in more detail with reference to FIG. 24.

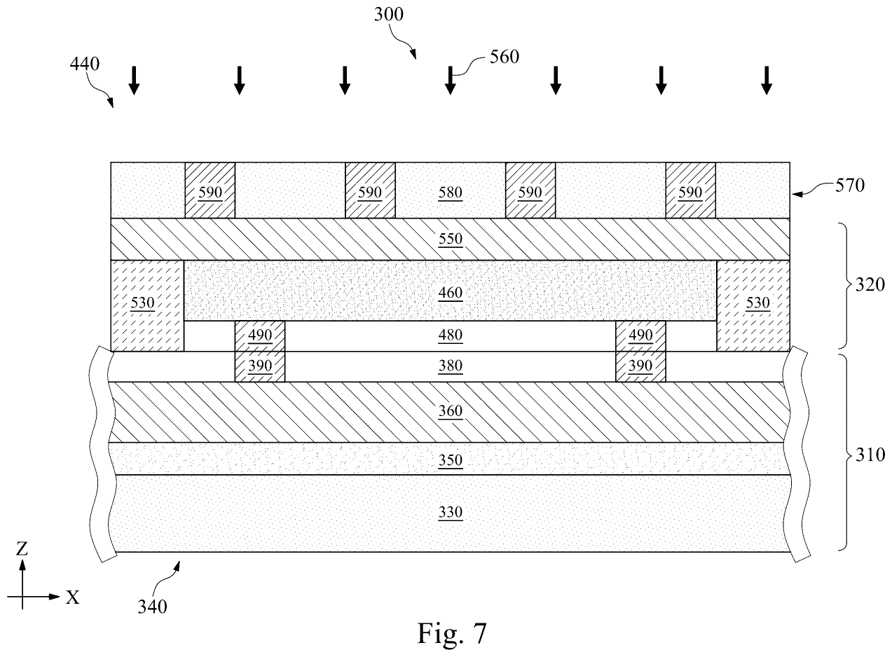

Referring now to FIG. 7, fabrication processes 560 are performed to the IC package assembly 300 to form a through-dielectric-via (TDV) structure 570 over the PDN structure 550 on the side 440. In more detail, the fabrication processes 560 may include a deposition process (e.g., CVD, PVD, ALD, etc.) to form a dielectric layer 580 over the surface of the PDN structure 550 that is exposed to the side 440. In some embodiments, the dielectric layer 580 may include silicon oxide, silicon nitride, silicon carbide, silicon oxynitride, or another suitable dielectric material that is configured to provide electrical insulation. The fabrication processes 560 may also include one or more etching processes to etch a plurality of openings in the dielectric layer 580, as well as deposition processes to fill these etched openings with a conductive material (e.g., copper, aluminum, ruthenium, cobalt, tungsten, etc.), thereby forming the vias 590 that extend vertically through the dielectric layer 580 in the Z-direction. The dielectric layer 580 and the vias 590 may collectively make up the TDV structure 570. The TDV structure 570 may serve as an interconnection structure for establishing electrical interconnections for the IC package assembly 300.

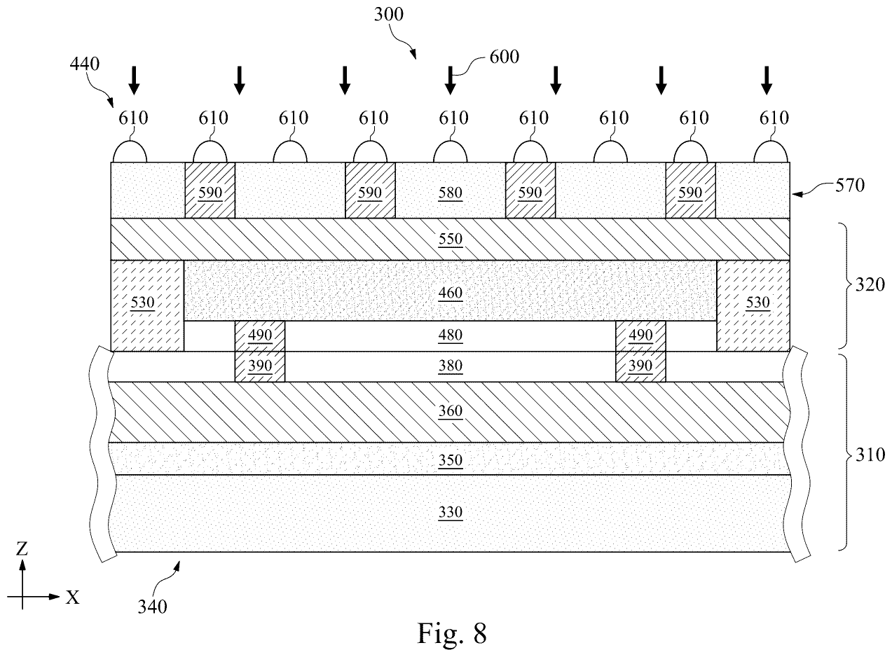

Referring now to FIG. 8, fabrication processes 600 are performed to the IC package assembly 300 to form a plurality of conductive bumps 610 over the TDV structure 570 on the side 440. In some embodiments, the conductive bumps 610 may include a metal, a metal compound, or a metal alloy. In some embodiments, the conductive bumps 610 may include solder balls. It is understood that the conductive bumps 610, the vias 590, and the PDN structure 550 may be electrically coupled together, such that electrical connectivity to the IC package assembly 300 may be gained through the conductive bumps 610, the vias 590, and the PDN structure 550.

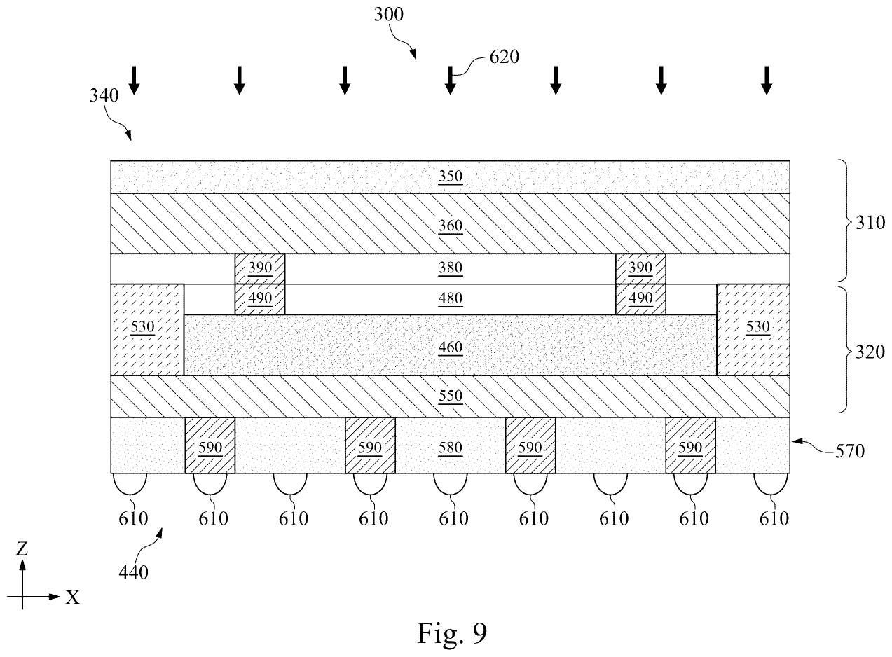

Referring now to FIG. 9, fabrication processes 620 may be performed to the IC package assembly 300. As a part of the fabrication processes 620, the IC package assembly 300 is flipped upside down vertically in the Z-direction, such that the side 340 and the side 440 are switched. The fabrication processes 620 includes a wafer thinning process, which is performed from the side 340 of the PIC device 310. The wafer thinning process may include a mechanical grinding process and/or a chemical thinning process, which may be performed until the photonic I/O structure 350 is exposed to the side 340.

The fabrication processes 620 may also include a dicing process. For example, a mechanical saw or a laser saw may be used to dice the IC package assembly 300 in the vertical Z-direction, such that the IC package assembly 300 is singulated into a desired number of smaller pieces. For example, the dicing may occur at the locations of the gap filling materials 530 in some embodiments. As a result, each of the singulated pieces may still include the PIC device 310, as well as a portion of the EIC device 320 that is coupled to the PIC device 310. Such a singulated piece may constitute an individual IC package assembly 300 that can be sold and/or used in an application to transmit signals from other ICs, for example, signals that carry data corresponding to the computational results of GPUs/CPUs that are communicatively coupled to the IC package assembly 300.

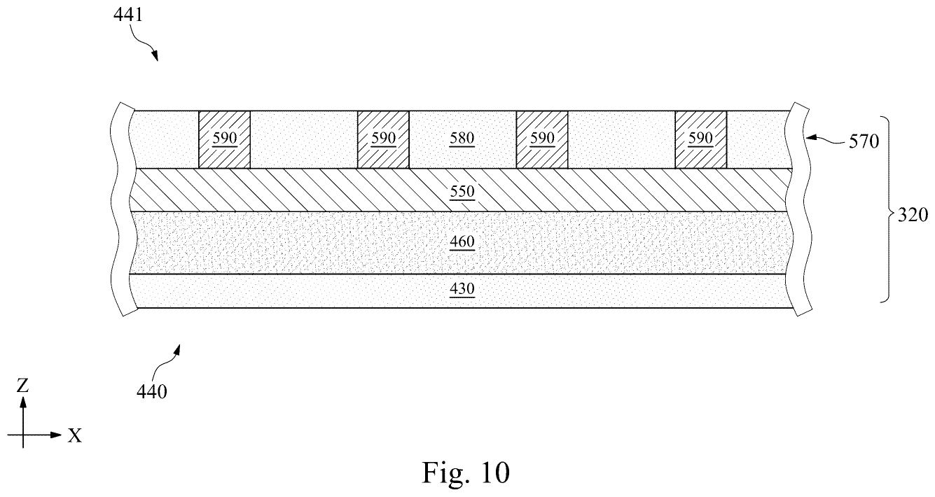

FIGS. 2-9 correspond to one embodiment of the fabrication process flow of the present disclosure. FIGS. 10-23 correspond to another embodiment of the fabrication process flow of the present disclosure. For reasons of consistency and clarity, similar components appearing in FIGS. 2-23 will be labeled the same hereinafter.

Referring now to FIG. 10, an EIC device 320 is provided. The EIC device 320 at this stage is a wafer-level structure. For example, the EIC device 320 includes the wafer-level substrate 430 (e.g., a silicon wafer), as well as the layer 460 that contains an interconnection structure and electrical circuitry (e.g., a microcontroller) for interacting with the photonic components of the PIC. The substrate 430 is disposed on the side 440 of the EIC device 320, and the layer 460 is disposed over the substrate 430 on the side 441.

The EIC device 320 of FIG. 10 also includes the PDN structure 550 that is configured to deliver power and ground voltages from conductive pad locations to the various components (e.g., the electrical circuitry of the layer 460). As such, the PDN structure 550 may include power rails and/or ground rails. The PDN structure 550 is disposed over the layer 460 on the side 441. Otherwise, the formation of the PDN structure 550 may be achieved via fabrication processes similar to the fabrication processes 540 discussed above with reference to FIG. 6.

The EIC device 320 of FIG. 10 further includes the TDV structure 570, which includes the dielectric layer 580 and the vias 590 that extend vertically through the dielectric layer 580 in the Z-direction. The TDV structure 570 is disposed over the PDN structure 550 on the side 441. Otherwise, the formation of the TDV structure 570 may be achieved via fabrication processes similar to the fabrication processes 560 discussed above with reference to FIG. 7.

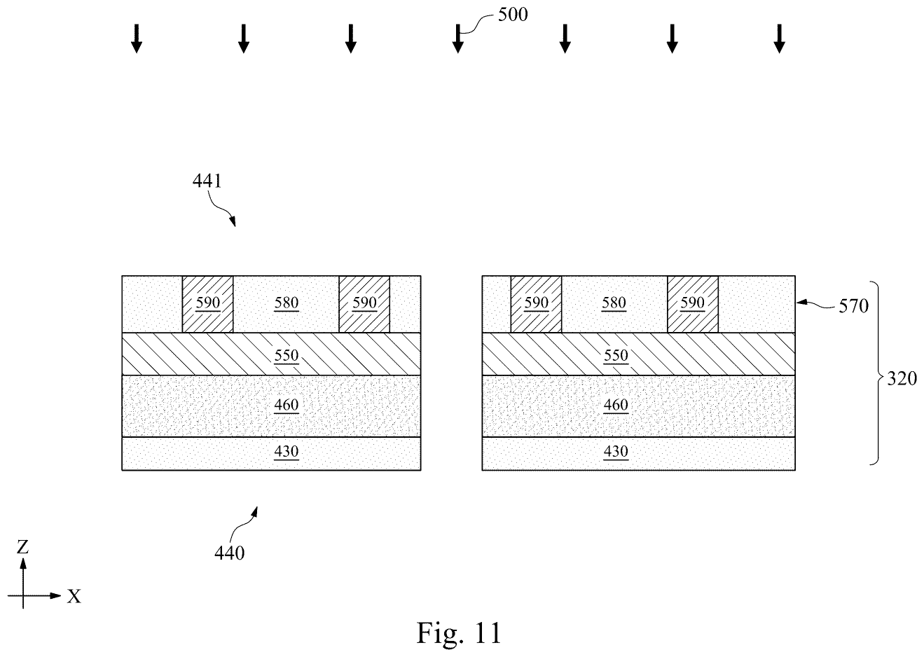

Referring now to FIG. 11, the fabrication processes 500 may be performed to the EIC device 320. As discussed above with reference to FIG. 3, the fabrication processes 500 may include a dicing process and a die thinning process. As a result of the dicing process, the wafer-level structure of EIC device 320 may be singulated into a plurality of smaller pieces, where each of the smaller pieces may now be referred to as the EIC device 320 hereinafter. Meanwhile, as a result of the die thinning process (e.g., performed from the side 440), the EIC device 320 may have a substantially thinner substrate 430 in the Z-direction. It is understood that the dicing process may be performed before the die thinning process in some embodiments or after the die thinning process in some other embodiments.

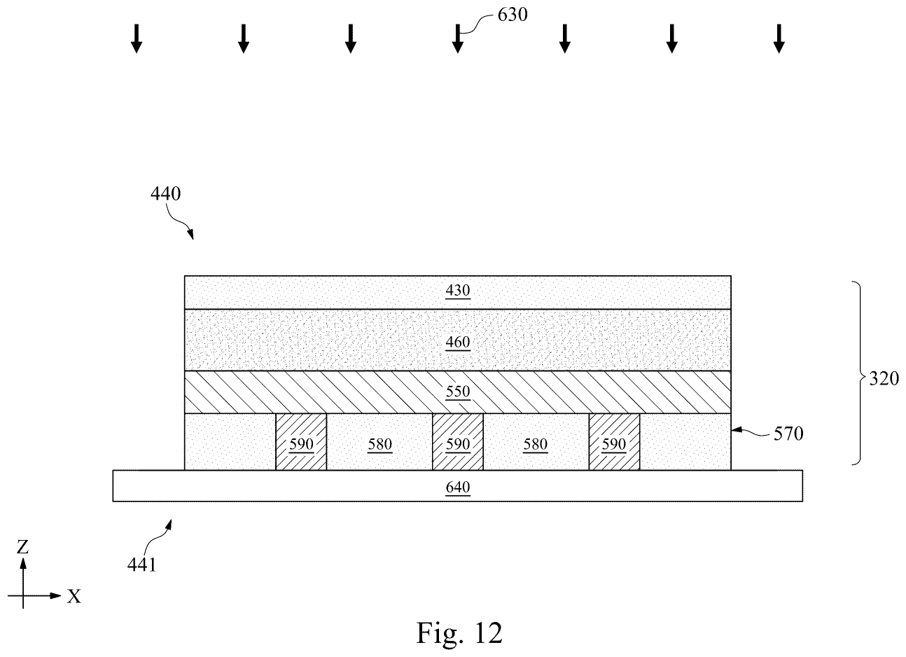

Referring now to FIG. 12, a coupling process 630 may be performed to couple the EIC device 320 (i.e., the singulated individual piece) to a carry wafer 640. For example, the EIC device 320 may be flipped vertically upside down in the Z-direction, such that the side 440 and the side 441 are switched. The EIC device 320 is then coupled to the carry wafer 640 through the side 441 as a part of the coupling process 630. In some embodiments, the coupling process 630 may include a pick-and-place process. In some embodiments, the carry wafer 640 is a wafer-level structure, such as a silicon wafer. It is understood that a plurality of the EIC devices 320 may be coupled to the same carry wafer 640, but the coupling of just one of the EIC devices 320 and the carry wafer 640 is illustrated in FIG. 12 for reasons of simplicity.

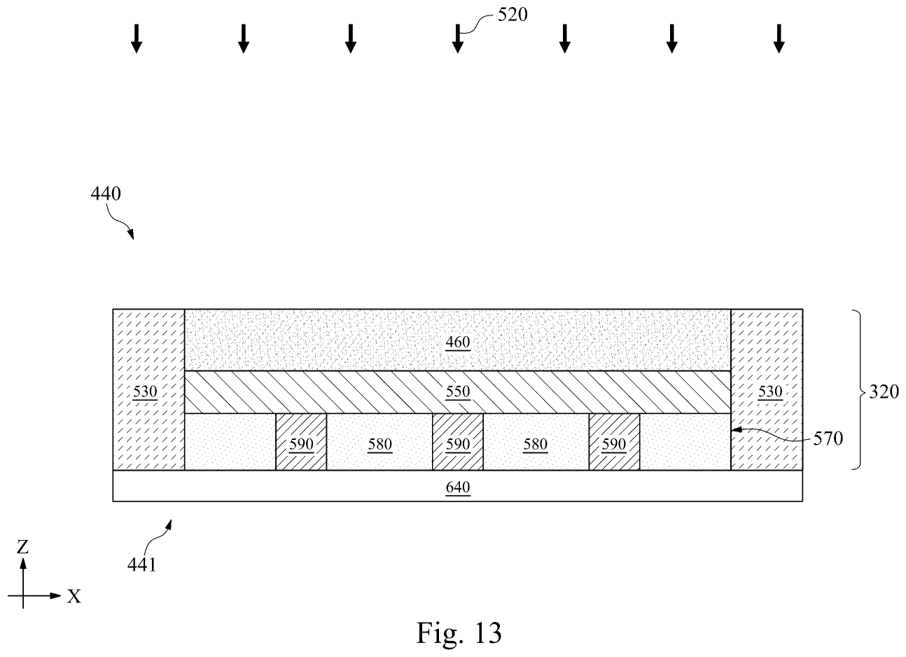

Referring now to FIG. 13, the fabrication processes 520 discussed above with reference to FIG. 5 are performed to the EIC device 320. For example, the fabrication processes 520 may include a grinding process that is performed from the side 440 to remove the substrate 430 and to expose the layer 460 to the side 440. The grinding process also ensures that the exposed surface of the layer 460 has a sufficient flatness and/or smoothness for subsequent fabrication processing. The fabrication processes 520 may also include one or more deposition processes to form the gap filling material 530 to fill the gaps formed as a result of the EIC device 320 having a narrower lateral dimension than the carry wafer 640 in the X-direction. The gap filling material 530 may be deposited onto the surfaces of the carry wafer 640 exposed to the side 440 (i.e., the portions that are not covered by the EIC device 320), and it also laterally surrounds the side surfaces of the EIC device 320. In some embodiments, the gap filling material 530 may include a suitable dielectric material, such as silicon carbide, silicon nitride, silicon oxide, silicon oxynitride, or combinations thereof.

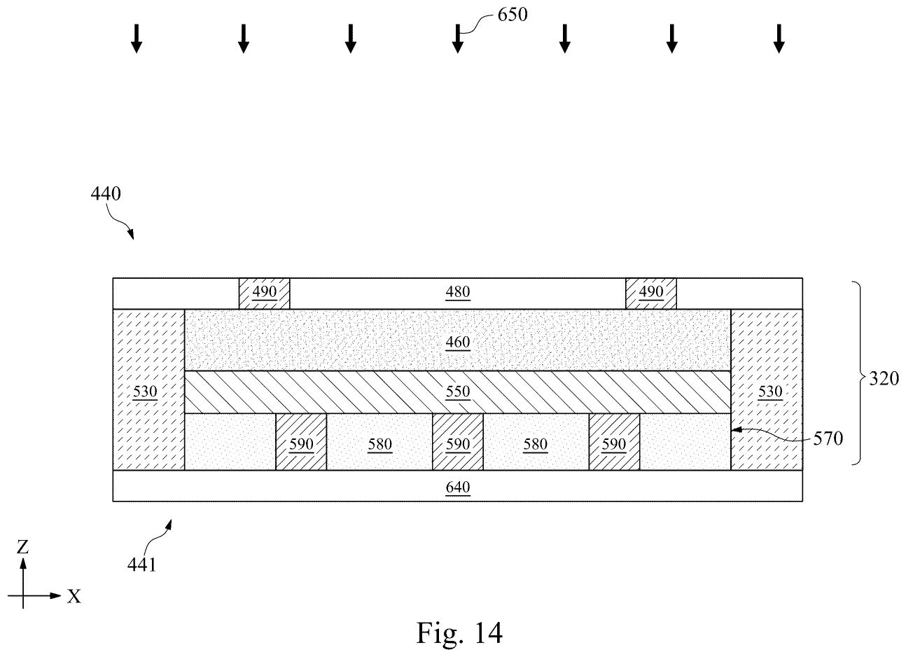

Referring now to FIG. 14, fabrication processes 650 may be performed to form the bonding film 480 over the side 440 of the EIC device 320. As discussed above, the bonding film 480 may include a dielectric material, such as silicon oxide or silicon oxynitride in various embodiments. The plurality of vias 490 may be disposed within and extend vertically through the bonding film 480. Again, the conductive vias 490 may be used to align the EIC device 320 the PIC device 310 in a bonding process that bonds later.

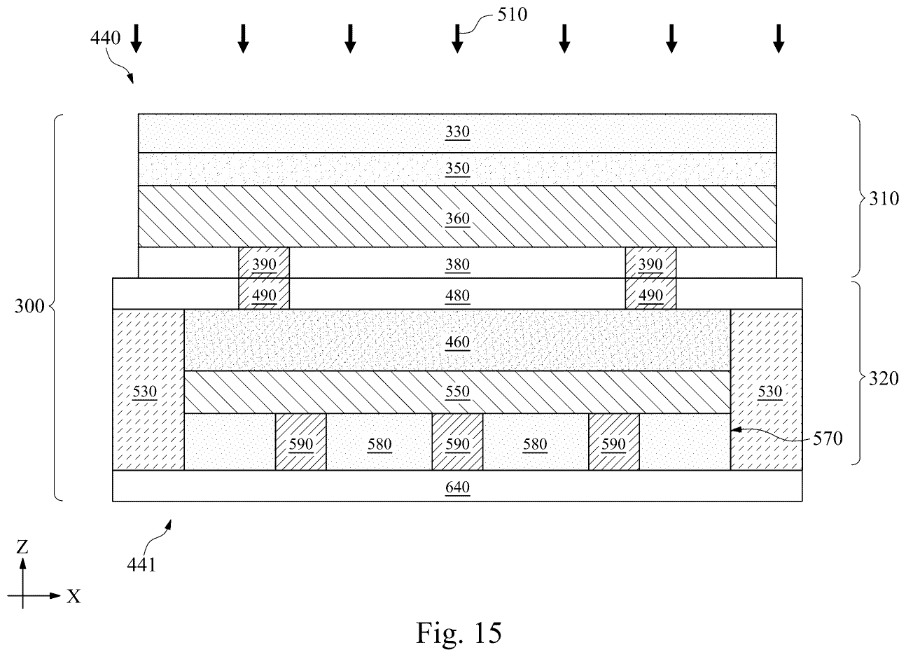

Referring now to FIG. 15, the coupling process 510 discussed above with reference to FIG. 4 is performed to couple the EIC device 320 the PIC device 310 together. Note that the PIC device 310 at this stage of fabrication has already undergone a dicing process and a die thinning process. In other words, the PIC device 310—which includes the substrate 330, the interconnection structure 360, and the photonic I/O structure 350 disposed between the substrate 330 and the interconnection structure 360—has already been singulated into a plurality of smaller individual pieces, and the thickness of the substrate 330 has also been reduced substantially. Note that the PIC device 310 may also include the bonding film 380, which includes a plurality of conductive vias 390 that extend vertically therethrough. The coupling process 510 may be performed by bonding the bonding film 380 with the bonding film 480, including by ensuring that each pair of the conductive vias 390 and 490 is aligned and electrically coupled together. Through the vias 390 and 490, electrical connectivity between the PIC device 310 and the EIC device 320 may be established. The PIC device 310 and the EIC device 320 may collectively constitute the IC package assembly 300.

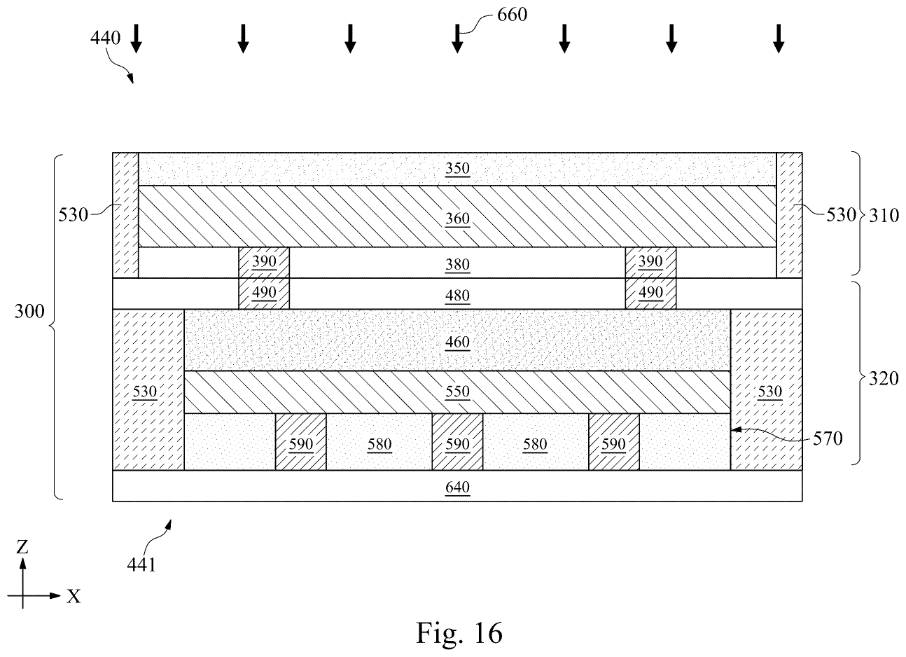

Referring now to FIG. 16, fabrication processes 660 may be performed to the IC package assembly 300. The fabrication processes 660 may include a grinding process that is performed from the side 440 to remove the substrate 330 from the rest of the PIC device 310. The removal of the substrate 330 exposes the photonic I/O structure 350 to the side 440. The grinding process also ensures that the exposed surface of the photonic I/O structure 350 has a sufficient flatness and/or smoothness for subsequent fabrication processing. The fabrication processes 660 may also include one or more deposition processes to form additional portions of the gap filling material 530 to fill the gaps formed as a result of the PIC device 310 having a narrower lateral dimension than the EIC device 320 in the illustrated embodiment. The gap filling material 530 may include a suitable dielectric material and may be deposited onto the surfaces of the bonding film 480 exposed to the side 440 (i.e., the portions that are not covered by the PIC device 310), and it also laterally surrounds the side surfaces of the PIC device 310 (e.g., the side surfaces of the photonic I/O structure 350 and the interconnection structure 360).

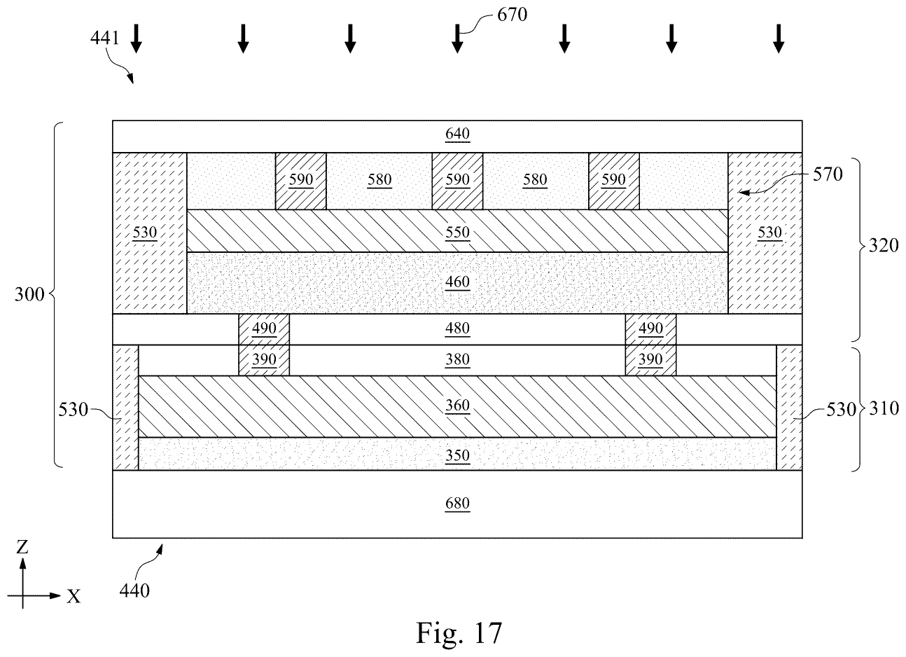

Referring now to FIG. 17, fabrication processes 670 may be performed to the IC package assembly 300. First, the IC package assembly 300 is flipped vertically upside down in the Z-direction, such that the sides 440 and 441 are switched again. Now the carry wafer 640 is facing upward, and the photonic I/O structure 350 is facing downward in FIG. 17. The fabrication processes 670 may include a coupling process that couples a carrier wafer 680 to the IC package assembly 300 from the side 440. In some embodiments, the carrier wafer 680 includes a glass wafer. In other embodiments, the carrier wafer 680 may include a sapphire wafer or a silicon wafer. In some embodiments, the coupling of the carrier wafer 680 with the IC package assembly 300 may include a bonding process.

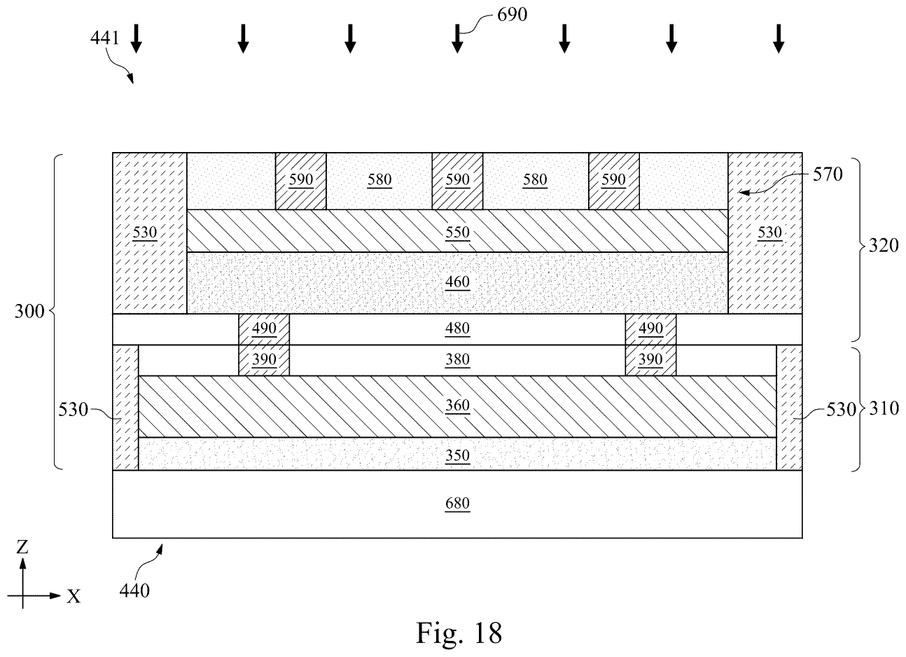

Referring now to FIG. 18, a removal process 690 is performed to the IC package assembly 300 to remove the carry wafer 640 from the rest of the IC package assembly 300. In some embodiments, the removal process 690 includes a debonding process. The removal of the carry wafer 640 exposes the upper surfaces of the TDV structure 570 and the gap filling material 530 to the side 441.

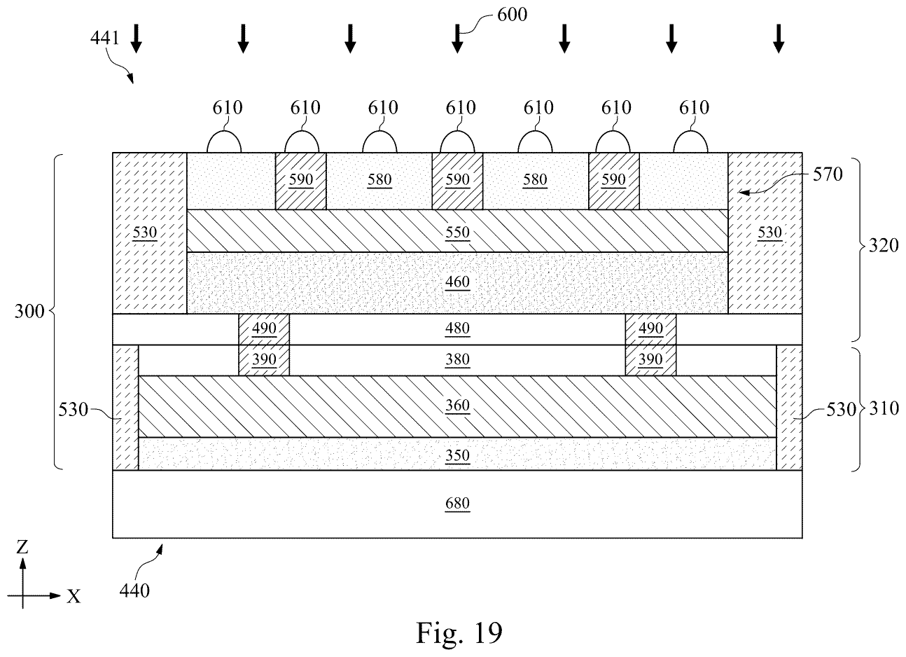

Referring now to FIG. 19, the fabrication processes 600 discussed above with reference to FIG. 8 are performed to the IC package assembly 300 to form the plurality of conductive bumps 610 over the TDV structure 570 on the side 441. In some embodiments, the conductive bumps 610 may include a metal, a metal compound, or a metal alloy. In some embodiments, the conductive bumps 610 may include solder balls. It is understood that the conductive bumps 610, the vias 590, and the PDN structure 550 may be electrically coupled together, such that electrical connectivity to the IC package assembly 300 may be gained through the conductive bumps 610, the vias 590, and the PDN structure 550.

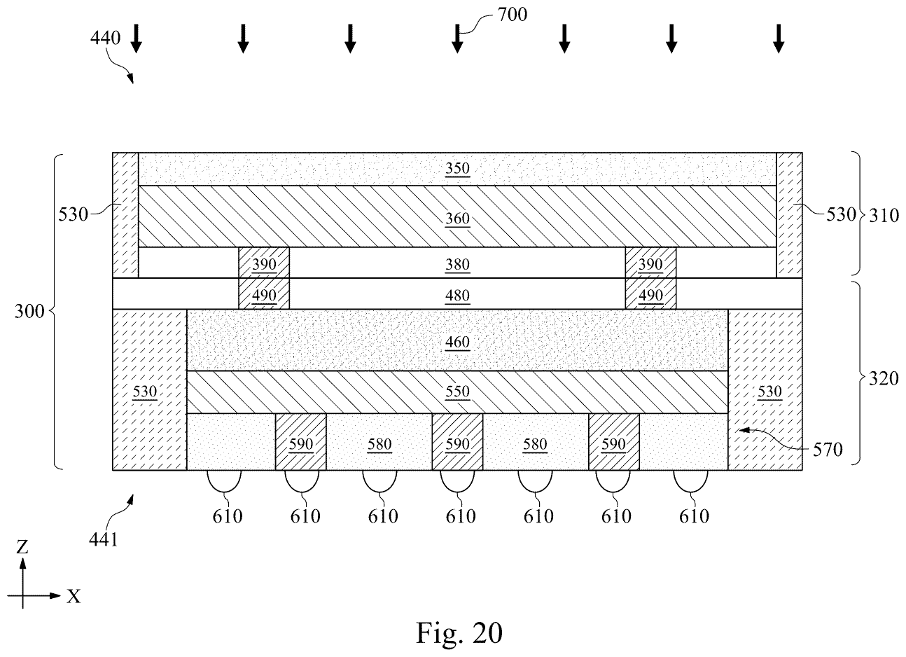

Referring now to FIG. 20, fabrication processes 700 may be performed to the IC package assembly 300. In more detail, the IC package assembly 300 is flipped upside down vertically in the Z-direction again. The fabrication processes 700 may include a removal process to remove the carrier wafer 680 from the rest of the IC package assembly 300. For example, the removal process may include a carrier wafer debonding process. The fabrication processes 700 may also include a die saw process, which may separate the IC package assembly 300 into smaller singulated pieces. Each of the singulated pieces (i.e., the IC package assembly 300 shown in FIG. 20) may be sold and/or used in an application to transmit signals from other ICs, for example, signals that carry data corresponding to the computational results of GPUs/CPUs that are communicatively coupled to the IC package assembly 300.

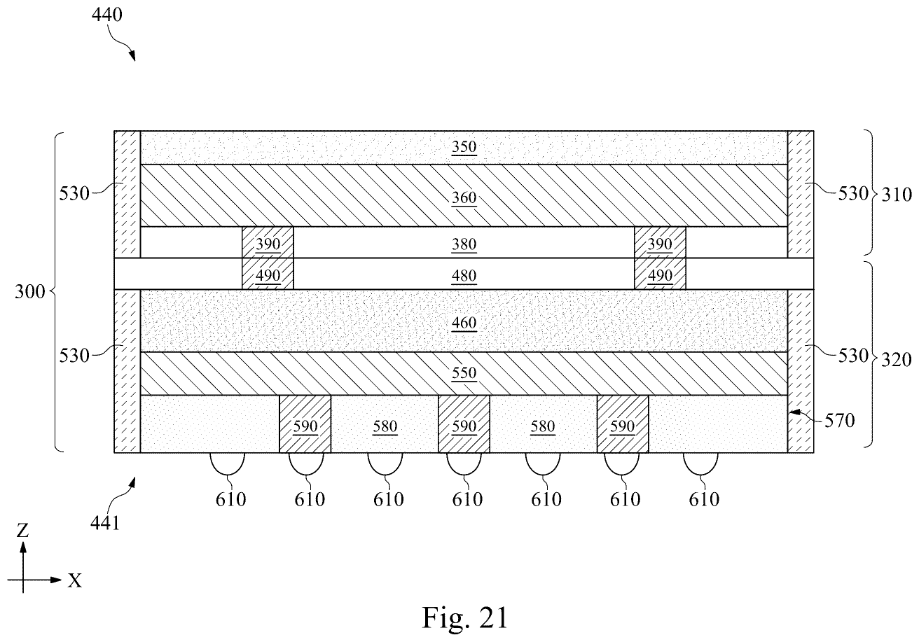

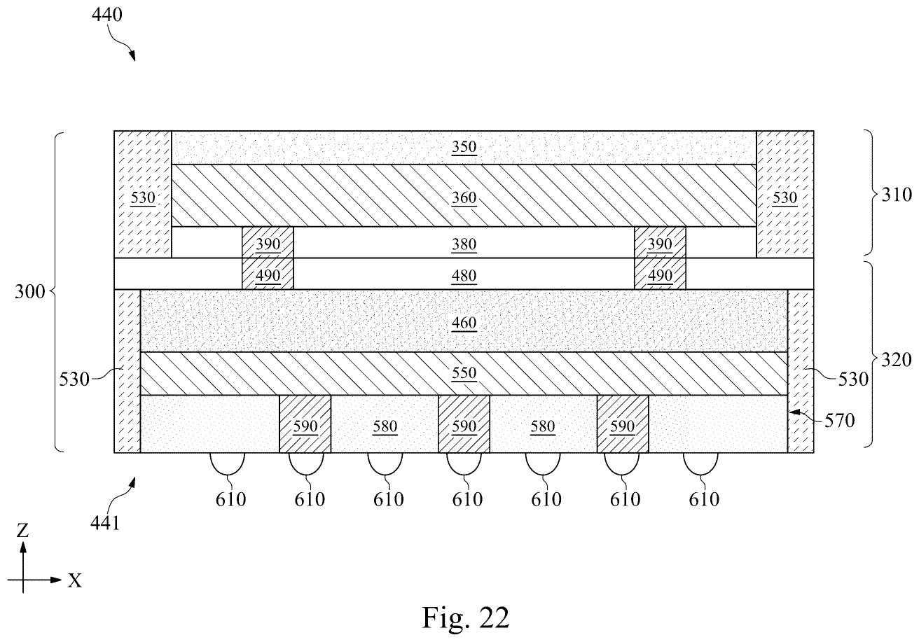

FIG. 20 corresponds to an embodiment of the IC package assembly 300 where the PIC device 310 has a greater lateral dimension in the X-direction than the EIC device 320. However, this need not be the case, and that other relative dimensions between the PIC device 310 and the EIC device 320 may be implemented in other embodiments. For example, in an alternative embodiment shown in FIG. 21, the PIC device 310 and the EIC device 320 may have substantially equal lateral dimensions in the X-direction. As another example, in another alternative embodiment shown in FIG. 22, the PIC device 310 may have a smaller lateral dimension than the EIC device 320 in the X-direction.

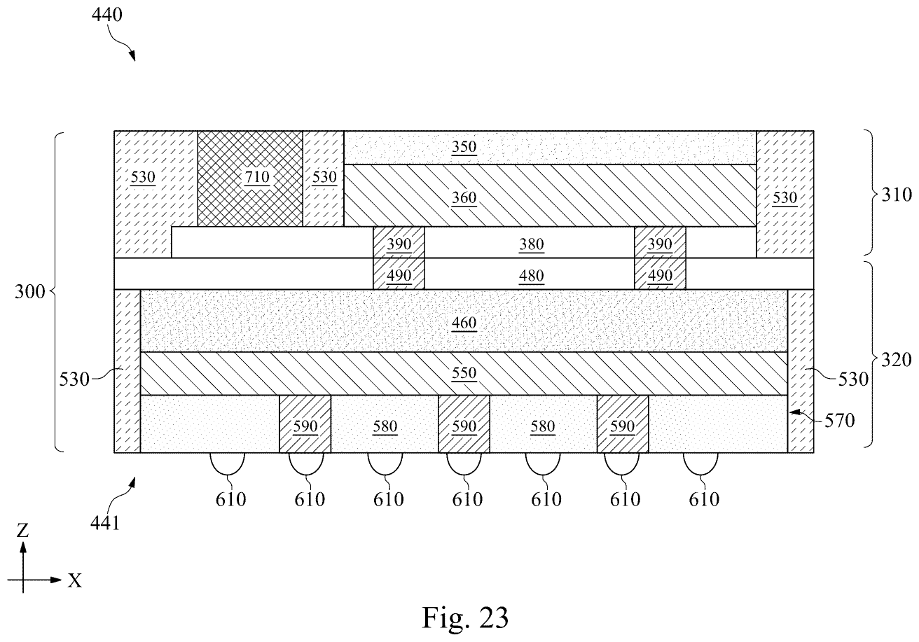

FIG. 23 illustrates yet another embodiment of the present disclosure, where an IC die 710, in addition to the PIC device 310 and the EIC device 320, is implemented as a part of the IC package assembly 300. In more detail, the IC die 710 may be formed over the bonding film 380 on the side 440. The IC die 710 may also be formed laterally adjacent to the rest of the PIC device 310 (e.g., the photonic I/O structure 350 and the interconnection structure 360) but may or may not be directly touching the side surfaces of the photonic I/O structure 350 and the interconnection structure 360. For example, in the embodiment of FIG. 23, a portion of the gap filling material 530 may be disposed between the IC die 710 and the rest of the PIC device 310.

One purpose of the IC die 710 is to ensure that any extra space created as a result of the size lateral difference between the EIC device 320 and the PIC device 310 is substantially filled. In some embodiments, the IC die 710 may be a dummy die that does not contain functional electrical or optical circuitry, but instead it may mostly serve as a space-filler to ensure that the area surrounding the PIC device 310 may be sufficiently flat or smooth. For example, an upper surface of such a dummy die (e.g., as an embodiment of the IC die 710) may be substantially co-planar with the upper surface of the photonic I/O structure 350.

The IC package assembly 300 of the present disclosure derives benefits as an inherent result of the specific manner in which the PDN structure 550 is implemented. This is explained in more detail with reference to FIG. 24, which is a cross-sectional side view that illustrates a portion of the EIC device 320, including the PDN structure 550 and the layer 460. As discussed above, the layer 460 includes electrical circuitry, such as electrical circuitry 720 made of transistors (e.g., the FinFET or GAA devices discussed above with reference to FIGS. 1A-1C) that are formed in and/or on a substrate 730 (e.g., a silicon substrate). The layer 460 also includes an interconnection structure 740 formed over the side 440 of the substrate 730. The interconnection structure 740 may include a plurality of interconnect layers (e.g., M0, M1, M2, etc.) that include metal lines interconnected by a plurality of conductive vias. The interconnection structure 740 may be used to propagate or transmit electrical signals emitted by the electrical circuitry 720.

Meanwhile, the PDN structure 550 is disposed over the side 441 of the substrate 730 (i.e., an opposite side than the interconnection structure 740). The PDN structure 550 may also include a plurality of interconnect layers (e.g., M0, M1, M2, etc.) that include metal lines interconnected by a plurality of conductive vias (including through-substrate-vias (TSVs)). However, unlike the interconnection structure 740, the PDN structure 550 may be configured to provide electrical power or electrical ground for the electrical circuitry 720. For example, the PDN structure 550 may include VDD rails as the electrical power rails, as well as VSS rails as the electrical ground rails.

The fact that the PDN structure 550 and the interconnection structure 740 are located on the opposite sides of the electrical circuitry 720 is beneficial. For example, the separation of the PDN structure 550 from the interconnection structure 740 allows for greater spacing among the conductive components (e.g., metal lines and/or conductive vias) in not only the PDN structure 550 itself, but also in the interconnection structure 740. This is because each structure (e.g., either the PDN structure 550 or the interconnection structure 740) now contains fewer conductive components that need to be kept physically separated from one another in order to avoid undesirable electrical shorting, and fewer components translate into more design flexibility and greater spacing among the components. As such, the manner in which the PDN structure 550 is implemented in the IC package assembly 300 herein reduces potential defects associated with electrical shorting, which would have occurred more commonly in IC package assemblies where its PDN structure (e.g., the structure including power and ground rails) is implemented on the same side as the rest of the interconnection structure that provides electrical routing for the electrical circuitry. The separation of the PDN structure 550 and the interconnection structure 740 may also allow further IC miniaturization to take place, since there is greater design flexibility (e.g., the PDN structure 550 and the interconnection structure 740 will not be the bottlenecks of miniaturization). Furthermore, the looser spacing among the conductive components of the PDN structure 550 and the interconnection structure 740 means that fewer lithography steps need to be performed, which lowers fabrication costs and shortens fabrication time.

The manner in which the PDN structure 550 is implemented in the IC package assembly 300 herein also leads to performance enhancements. For example, had the PDN structure 550 and the interconnection structure 740 been implemented on the same side, not only would that lead to smaller spacing among the conductive components (e.g., metal lines and/or conductive vias) of these structures, but the actual dimensions (e.g., the width of a metal line or an area of a via) of these structures would also have been smaller in order to avoid electrical shorting. Unfortunately, smaller sizes for the conductive components would also translate into greater electrical resistance. This in turn may lead to a larger voltage drop, excessive power consumption, and/or slower speed during the operation of the IC. In comparison, as an inherent result of separating the PDN structure 550 and the interconnection structure 740 to different sides, the conductive components in these structures may now be implemented with larger sizes, which reduces electrical resistance and power consumption and/or improves the speed of the operation of the IC package assembly 300.

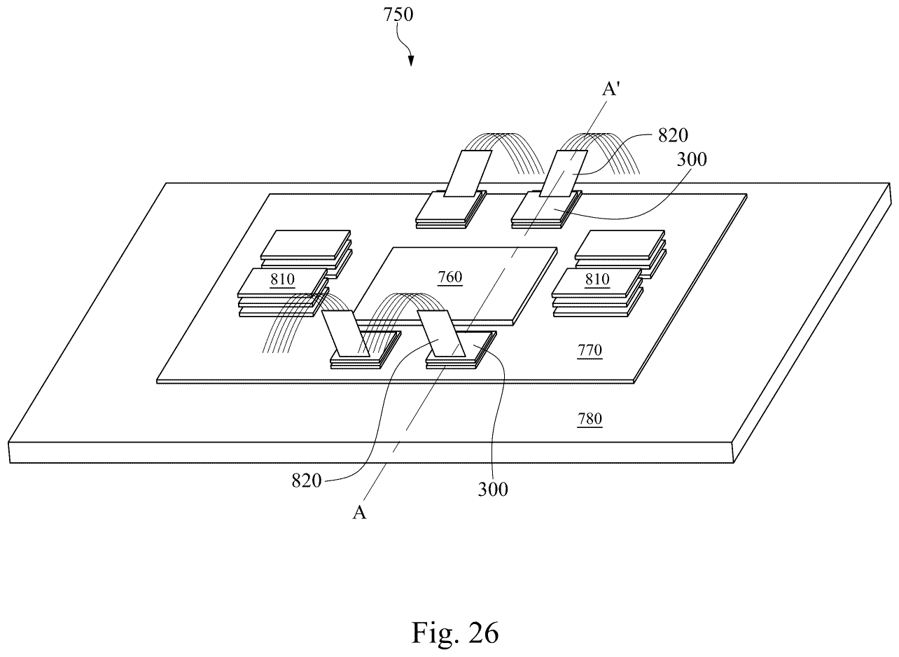

The implementation of the PDN structure 550 in the IC package assembly 300 herein also inherently improves optical efficiency, since the optical path is inherently made shorter. For example, referring now to FIGS. 25-26, a diagrammatic fragmentary cross-sectional side view and a three-dimensional perspective view of an IC device 750 are illustrated, respectively. The cross-sectional side view of FIG. 25 may be taken along a cutline A-A′ in the three-dimensional perspective view of FIG. 26.

As shown in FIGS. 25-26, the IC device 750 includes a plurality of instances of the IC package assembly 300 discussed above. The IC device 750 also includes a processing unit 760, such as a graphical processing unit (GPU) or a central processing unit (CPU). The processing unit 760 and the IC package assemblies 300 are each disposed over an interposer structure 770, which may include a silicon material in some embodiments. The interposer structure 770 itself is also disposed over, and electrically coupled to, a substrate 780. The processing unit 760 is electrically coupled to each of the IC package assemblies 300 through a plurality of conductive bumps 790. For example, the processing unit 760 may be electrically coupled to the IC package assembly 300 disposed to its “left” through a first subset of the conductive bumps 790, and the processing unit 760 may be electrically coupled to the IC package assembly 300 disposed to its “right” through a second subset of the conductive bumps 790. In some embodiments, the first subset and/or the second subset of the conductive bumps 790 may be electrically coupled to the TDV structure 570, for example, to one of the conductive vias 590 of the TDV structure 570. Another subset of the conductive bumps 790 may also be electrically coupled to the substrate through a plurality of conductive bumps 800 that are disposed between the interposer structure 770 and the substrate 780. In addition, a plurality of electronic memory devices 810 (e.g., random access memory) may be implemented on the interposer structure 770, as shown in FIG. 26. These electronic memory devices 810 are not directly visible in FIG. 25, since they are located outside the cutline A-A′.

The IC device 750 also includes a light source and/or receiver, such as a fiber array unit 820. The fiber array unit 820 may be positioned over and/or extend at least partially through the photonic I/O structure 350. For example, the fiber array unit 820 may be vertically aligned with one or more of the microlenses of the photonic I/O structure 350. This type of fiber array unit 820 may be referred to as a grating coupler. The fiber array unit 820 may include an array of units that are each configured to generate light, and/or to receive light. The light may propagate through the microlens (and/or other components of the photonic I/O structure 350), which will focus the light on an intended target within the IC package assembly 300. Using the light as inputs/outputs, the IC package assembly 300 may help transmit and/or process electrical signals corresponding to computational results generated by the processing unit 760.

In other types of IC devices that utilize a photonic device for data transmission or processing, the photonic device may be bonded to an interposer structure similar to the interposer structure 770, and the electronic device (e.g., for controlling the photonic device) may be located over the photonic device. There are several drawbacks with such an approach. First, a support layer (e.g., a silicon layer) may need to be grown on the electronic device, and such a support layer may need to be etched to create one or more curved surfaces that can serve as microlenses to focus light onto the intended target. In addition, the substrate of the photonic device may need to be removed in such a scheme. These fabrication requirements increase manufacturing complexity and cost. Furthermore, the intended target for the light is often located near the bottom of the photonic device. As such, light has to travel through not just the support layer, but also through the electronic device, as well as a portion of the photonic device, before reaching the intended target. Such a long light propagation path may lead to loss of optical energy, thereby degrading the performance of the photonic device. The light propagation path may also pass through one or more interfaces between the photonic device and other devices, which could lead to light reflections that would further increase the loss of optical energy. Furthermore, such a scheme also requires a portion of the electronic device and the photonic device to be reserved (e.g., be free of other structures such as interconnection components) for the light transmission. Such a requirement also reduces the effective usable area of the electronic device and/or the photonic device.

In comparison, the IC package assembly 300 herein utilizes novel fabrication process flows to implement the PDN structure 550 on the side of the EIC device 320 that is facing away from the PIC device 310, which also allows the photonic I/O structure 350 to be located at the topmost level. Such a unique implementation scheme inherently allows for light to travel a short distance (e.g., through just the photonic I/O structure 350) to reach the intended target. In other words, optical energy can be input and/or output near a surface of the PIC device 310 (e.g., at a location above the interconnection structure 360). Such a scheme further reduces losses incurred due to light reflections within the IC package assembly 300. For these reasons, the IC package assembly 300 herein may have reduced loss of optical energy and will therefore have better device performance. In addition, whereas the other types of implementation schemes reserve just a small area for inputting/outputting light, the IC package assembly 300 may take advantage of the entirety of the photonic I/O structure 350 to do so, which may further improve device performance. Furthermore, since no portion of the PIC device 310 or the EIC device 320 needs to be specifically reserved for the light propagation path, the area or size of the PIC device 310 or the EIC device 320 may be enlarged compared to other types of implementation schemes, which allows more components to be implemented inside the PIC device 310 or the EIC device 320, which can further increase the sophistication and/or the functionality of these devices. Lastly, the unique fabrication process flows do not require the use of a support layer, which further simplifies the fabrication process and reduces the fabrication cost.

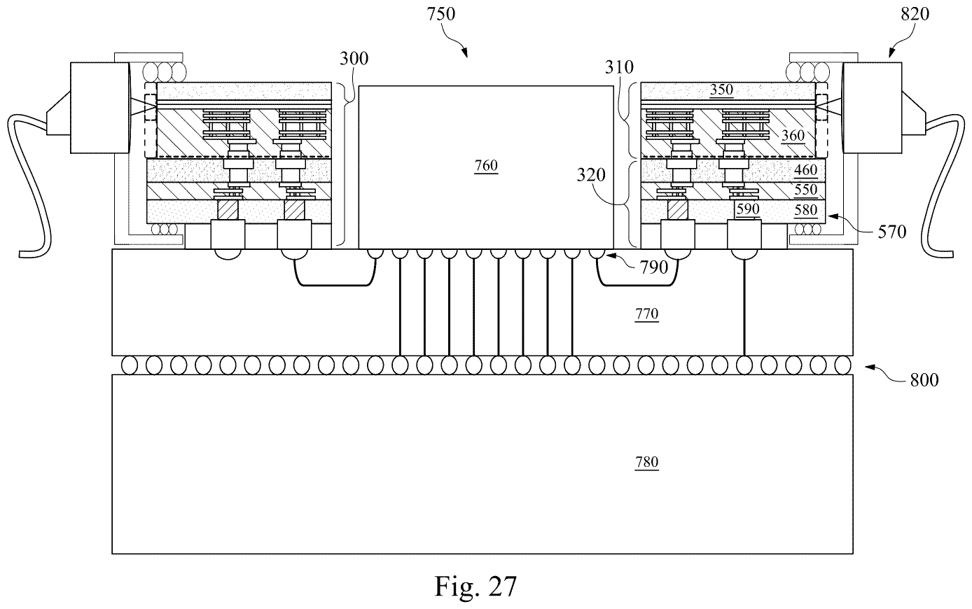

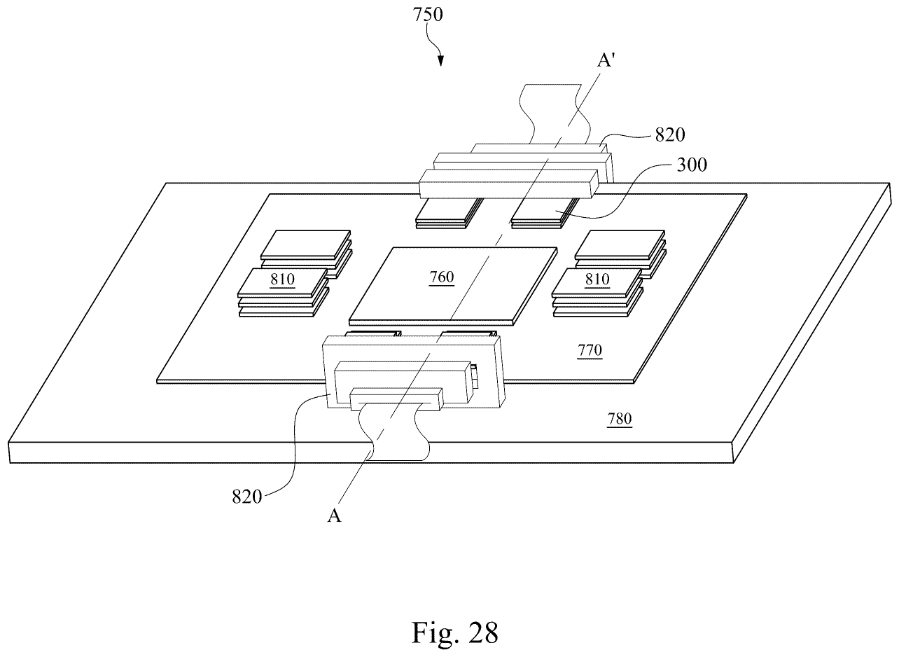

FIGS. 27-28 illustrates a diagrammatic fragmentary cross-sectional side view and a three-dimensional perspective view of an IC device 750, respectively, according to another embodiment of the present disclosure. For reasons of consistency and clarity, similar components appearing in FIGS. 25-28 will be labeled the same hereinafter. Referring to FIGS. 27-28, the IC device 750 also includes the processing unit 760 and a plurality of instances of the IC package assembly 300, which are located on an interposer structure 770 and are electrically coupled together. However, whereas the IC device 750 of FIGS. 25-26 utilizes a grating coupler for the fiber array unit 820, the IC device 750 of FIGS. 27-28 utilizes an edge coupler for the fiber array unit 820, where the fiber array unit 820 is disposed laterally adjacent to the PIC device 310 and transmits light from the side laterally. Advantageously, the horizontal plane coupling is not limited by the polarization effects of the waveguides of the PIC device 310, which then allows for an increase in the amount of information from a single optical input. Other than the difference in the location and/or type of fiber array unit 820, the embodiment of the IC device 750 of FIGS. 27-28 may enjoy the same benefits as the embodiment discussed above with reference to FIGS. 25-26.

FIG. 29 illustrates an integrated circuit fabrication system 900 that may be used to fabricate the IC package assembly 300 according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such an EUV tool that is used to perform lithography processes to define the various components of a transistor; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

FIG. 30 is a flowchart of a method 1000 of fabricating an integrated circuit (IC) package assembly according to various aspects of the present disclosure. The method 1000 includes a step 1010 to couple a first side of an electronic integrated circuit (EIC) device to a first side of a photonic integrated circuit (PIC) device. The PIC device includes a substrate, a first interconnection structure, and a photonic input/output (I/O) structure disposed between the substrate and the first interconnection structure. In some embodiments, the EIC device includes a first bonding film located at the first side of the EIC device, and the PIC device includes a second bonding film located at the first side of the PIC device. In some embodiments, the step 1010 comprises bonding the first bonding film to the second bonding film. In some embodiments, the EIC device further includes a set of first vias extending vertically through the first bonding film, and the PIC device further includes a set of second vias extending vertically through the second bonding film, and the bonding is performed at least in part by aligning each of the first vias with a respective one of the second vias.

The method 1000 includes a step 1020 to grind the EIC device from a second side of the EIC device opposite the first side of the EIC device.

The method 1000 includes a step 1030 to form a power delivery network (PDN) structure over the second side of the EIC device after the grinding.

The method 1000 includes a step 1040 to form a second interconnection structure over the PDN structure. In some embodiments, the step 1040 includes forming a dielectric layer over the PDN structure, forming plurality of through dielectric vias (TDVs) that each extend vertically through the dielectric layer, and forming a plurality of conductive bumps over the dielectric layer

The method 1000 includes a step 1050 to remove the substrate of the PIC device, thereby exposing the photonic I/O structure of the PIC device to a second side of the PIC device opposite the first side of the PIC device. In some embodiments, the photonic I/O structure includes a plurality of microlenses.

It is understood that the method 1000 may include further steps performed before, during, or after the steps 1010-1050. For example, the method 1000 may further include a step that is performed before the step 1010, where an EIC wafer is diced into a plurality of EIC pieces. The EIC device is one of the EIC pieces, and the PIC device to which the EIC device is coupled is a PIC wafer. As another example, the method 1000 may include a step before the step 1030, where a gap filling material is deposited over the PIC device. The gap filling material laterally surrounds the EIC device. For reasons of simplicity, other additional steps are not discussed herein in detail.

FIG. 31 is a flowchart of a method 1100 of fabricating an integrated circuit (IC) package assembly according to various aspects of the present disclosure. The method 1100 includes a step 1110 to provide an electronic integrated circuit (EIC) device that includes electrical circuitry, a first substrate disposed over a first side of the electrical circuitry, and a power delivery network (PDN) structure disposed over a second side of the electrical circuitry opposite the first side. In some embodiments, the step 1110 includes dicing an EIC wafer into a plurality of pieces. The EIC device is one of the pieces.

The method 1100 includes a step 1120 to place the EIC device on a carry wafer through the second side of the EIC device. In some embodiments, the EIC device includes a through dielectric via (TDV) structure disposed over the PDN structure on the second side, and the EIC device is placed on the carry wafer through the TDV structure.

The method 1100 includes a step 1130 to remove the first substrate from the first side of the EIC device after the EIC device has been placed on the carry wafer.

The method 1100 includes a step 1140 to couple a first side of a photonic integrated circuit (PIC) device to the first side of the EIC device. The PIC device includes a second substrate, an interconnection structure, and a photonic input/output (I/O) structure disposed between the second substrate and the interconnection structure.

The method 1100 includes a step 1150 to remove the second substrate of the PIC device. The photonic I/O structure is exposed after the second substrate has been removed.

It is understood that the method 1100 may include further steps performed before, during, or after the steps 1110-1150. For example, the method 1100 may further include a step that is performed before the step 1140, where a first bonding film is formed over the first side of the EIC device after the first substrate has been removed. The PIC device includes a second bonding film disposed over the interconnection structure, and the step 1140 comprises bonding the second bonding film to the first bonding film. As another example, the method 1100 may further include various steps that are performed after the step 1150, including a step of bonding a carrier wafer to the photonic I/O structure, a step of removing the carry wafer to expose the second side of the EIC device, a step of forming a plurality of conductive bumps on the exposed second side of the EIC device, and a step of debonding the carrier wafer after the conductive bumps have been formed. As yet another example, the method 1100 may further include a step that is performed after the step 1130 but before the step 1140, where a first gap filling material is deposited over the carry wafer. The first gap filling material laterally surrounds the EIC device. As yet another example, the method 1100 may further include a step that is performed after the step 1140, where a second gap filling material is deposited over the EIC device. The second gap filling material laterally surrounds the PIC device. For reasons of simplicity, other additional steps are not discussed herein in detail.

In summary, the present disclosure involves a unique process flow for fabricating an IC package assembly that includes an electronic IC (EIC) device and a photonic IC (PIC) device. The PIC device includes photonic components that can detect, process, or transmit light. The EIC device includes electronic circuitry that may include a microcontroller for controlling the operation of the PIC device. The IC package assembly implements a power delivery network (PDN) structure and an interconnection structure on opposite sides of a layer that includes electrical circuitry. As such, on one side of the layer that contains electrical circuitry, the PDN structure provides electrical power and ground rails, while on the other side of the layer that contains electrical circuitry, the interconnection structure provides electrical routing for the electrical circuitry.

The embodiments of the present disclosure offer advantages. It is understood, however, that other embodiments may offer additional advantages, and not all advantages are necessarily disclosed herein, and that no particular advantage is required for all embodiments. One advantage is the improved optical efficiency. In more detail, the IC package assembly of the present disclosure implements the photonic components at the top of the optical path, and therefore the optical path need not extend through the rest of the PIC device or the EIC device. The shorter optical path reduces a loss of optical energy and increases the efficiency of the PIC. Another advantage is better device performance. For example, by implementing the PDN structure and the interconnection structure on opposite sides of the electrical circuitry, there can be greater spacing among the conductive components in both the PDN structure and the interconnection structure. As a result, the conductive components can be made bigger, which leads to reduced electrical resistance and power consumption, and/or faster device speed. The greater spacing may also translate into a lower risk of undesirable electrical shorting. Another advantage is better utilization of IC device area. For example, whereas other types of IC package assemblies may have to reserve a small region for receiving/transmitting light, the IC package assembly of the present disclosure can utilize an entire surface area of the PIC device to receive/transmit light. In addition, the device area that would have been reserved for light transmission can now be free-up in the IC package assembly herein to form other IC components, which is a better utilization of precious chip real estate. Yet another advantage is that the unique fabrication process flow herein can eliminate the need for various support structures/layers that would have been needed in previous fabrication schemes. As a result, fabrication costs are reduced.

One aspect of the present disclosure pertains to a method of fabricating an integrated circuit (IC) package assembly. The method includes coupling a first side of an electronic integrated circuit (EIC) device to a first side of a photonic integrated circuit (PIC) device. The PIC device includes a substrate, a first interconnection structure, and a photonic input/output (I/O) structure disposed between the substrate and the first interconnection structure. The method includes grinding the EIC device from a second side of the EIC device opposite the first side of the EIC device. The method includes forming a power delivery network (PDN) structure over the second side of the EIC device after the grinding. The method includes forming a second interconnection structure over the PDN structure. The method includes removing the substrate of the PIC device, thereby exposing the photonic I/O structure of the PIC device to a second side of the PIC device opposite the first side of the PIC device.

Another aspect of the present disclosure pertains to a method of fabricating an integrated circuit (IC) package assembly. The method includes providing an electronic integrated circuit (EIC) device that includes electrical circuitry, a first substrate disposed over a first side of the electrical circuitry, and a power delivery network (PDN) structure disposed over a second side of the electrical circuitry opposite the first side. The method includes placing the EIC device on a carry wafer through the second side of the EIC device. The method includes removing the first substrate from the first side of the EIC device after the EIC device has been placed on the carry wafer. The method includes coupling a first side of a photonic integrated circuit (PIC) device to the first side of the EIC device, wherein the PIC device includes a second substrate, an interconnection structure, and a photonic input/output (I/O) structure disposed between the second substrate and the interconnection structure. The method includes removing the second substrate of the PIC device. The photonic I/O structure is exposed after the second substrate has been removed.

Another aspect of the present disclosure pertains to an integrated circuit (IC) package assembly. The IC package assembly includes a photonic integrated circuit (PIC) device and an electronic integrated circuit (EIC) device. The PIC device includes a plurality of photonic components. The photonic components are configured to receive light from a first side of the IC package assembly. The EIC device is bonded to the PIC device from a second side of the IC package assembly. The second side is opposite the first side. The EIC device includes a layer that contains electrical circuitry configured to interact with the photonic components of the PIC device. The EIC device also includes a power delivery network (PDN) structure. The layer is disposed between the PIC and the PDN structure of the EIC.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating an integrated circuit (IC) package assembly, comprising:
coupling a first side of an electronic integrated circuit (EIC) device to a first side of a photonic integrated circuit (PIC) device, wherein the PIC device includes a substrate, a first interconnection structure, and a photonic input/output (I/O) structure disposed between the substrate and the first interconnection structure;
grinding the EIC device from a second side of the EIC device opposite the first side of the EIC device;
forming a power delivery network (PDN) structure over the second side of the EIC device after the grinding;
forming a second interconnection structure over the PDN structure; and
removing the substrate of the PIC device, thereby exposing the photonic I/O structure of the PIC device to a second side of the PIC device opposite the first side of the PIC device.

2. The method of claim 1, wherein:
the EIC device includes a first bonding film located at the first side of the EIC device;
the PIC device includes a second bonding film located at the first side of the PIC device; and
the coupling comprises bonding the first bonding film to the second bonding film.

3. The method of claim 2, wherein:
the EIC device further includes a set of first vias extending vertically through the first bonding film;
the PIC device further includes a set of second vias extending vertically through the second bonding film; and
the bonding is performed at least in part by aligning each of the first vias with a respective one of the second vias.

4. The method of claim 1, further comprising, before the coupling, dicing an EIC wafer into a plurality of EIC pieces, wherein the EIC device is one of the EIC pieces, and wherein the PIC device to which the EIC device is coupled is a PIC wafer.

5. The method of claim 1, further comprising, before the forming of the PDN structure, depositing a gap filling material over the PIC device, wherein the gap filling material laterally surrounds the EIC device.

6. The method of claim 1, wherein the forming the second interconnection structure comprises:
forming a dielectric layer over the PDN structure;
forming plurality of through dielectric vias (TDVs) that each extend vertically through the dielectric layer; and
forming a plurality of conductive bumps over the dielectric layer.

7. The method of claim 1, wherein the photonic I/O structure includes a plurality of microlenses.

8. A method of fabricating an integrated circuit (IC) package assembly, comprising:
providing an electronic integrated circuit (EIC) device that includes electrical circuitry, a first substrate disposed over a first side of the electrical circuitry, and a power delivery network (PDN) structure disposed over a second side of the electrical circuitry opposite the first side;
placing the EIC device on a carry wafer through the second side of the EIC device;
removing the first substrate from the first side of the EIC device after the EIC device has been placed on the carry wafer;
coupling a first side of a photonic integrated circuit (PIC) device to the first side of the EIC device, wherein the PIC device includes a second substrate, an interconnection structure, and a photonic input/output (I/O) structure disposed between the second substrate and the interconnection structure; and
removing the second substrate of the PIC device, wherein the photonic I/O structure is exposed after the second substrate has been removed.

9. The method of claim 8, wherein the providing comprises dicing an EIC wafer into a plurality of pieces, and wherein the EIC device is one of the pieces.

10. The method of claim 8, wherein:
the EIC device includes a through dielectric via (TDV) structure disposed over the PDN structure on the second side; and
the EIC device is placed on the carry wafer through the TDV structure.

11. The method of claim 8, further comprising, before the coupling: forming a first bonding film over the first side of the EIC device after the first substrate has been removed;
wherein:
the PIC device includes a second bonding film disposed over the interconnection structure; and
the coupling comprises bonding the second bonding film to the first bonding film.

12. The method of claim 8, further comprising, after the second substrate of the PIC device has been removed:
bonding a carrier wafer to the photonic I/O structure;
removing the carry wafer, thereby exposing the second side of the EIC device;
forming a plurality of conductive bumps on the exposed second side of the EIC device; and
debonding the carrier wafer after the conductive bumps have been formed.

13. The method of claim 8, further comprising, after the removing of the first substrate but before the coupling: depositing a first gap filling material over the carry wafer, wherein the first gap filling material laterally surrounds the EIC device.

14. The method of claim 13, further comprising, after the coupling: depositing a second gap filling material over the EIC device, wherein the second gap filling material laterally surrounds the PIC device.

15. An integrated circuit (IC) package assembly, comprising:
a photonic integrated circuit (PIC) device that includes a plurality of photonic components, wherein the photonic components are configured to receive light from a first side of the IC package assembly; and
an electronic integrated circuit (EIC) device bonded to the PIC device from a second side of the IC package assembly, wherein the second side is opposite the first side, and wherein the EIC device includes:
a layer that contains electrical circuitry configured to interact with the photonic components of the PIC device; and
a power delivery network (PDN) structure, wherein the layer is disposed between the PIC and the PDN structure of the EIC.

16. The IC package of claim 15, wherein the PDN structure includes one or more power rails or ground rails.

17. The IC package of claim 15, further comprising:
a dielectric layer disposed over the PDN structure on the second side of the IC package assembly;
a plurality of through dielectric vias (TDVs) that extend vertically through the dielectric layer; and
a plurality of conductive bumps disposed over the dielectric layer on the second side of the IC package assembly.

18. The IC package of claim 15, wherein the photonic components include one or more microlenses.

19. The IC package of claim 15, further comprising a bonding structure bonded between the PIC device and the EIC device.

20. The IC package of claim 15, wherein the PIC device includes an interconnection structure disposed between the EIC device and the photonic components of the PIC device.
